(19) United States
(12) Patent Application Publication
(10) Pub. No.: US 2011/0084277 A1
(43) Pub. Date: Apr. 14, 2011

(54) SEMICONDUCTOR MEMORY DEVICE AND ITS MANUFACTURING METHOD

(75) Inventors: Koichi Kawashima, Toyama (JP); Nobuyoshi Takahashi, Toyama (JP); Yuichiro Higuchi, Toyama (JP)

(73) Assignee: PANASONIC CORPORATION, Osaka (JP)

(21) Appl. No.: 12/973,292

(22) Filed: Dec. 20, 2010

Related U.S. Application Data
(62) Division of application No. 12/178,234, filed on Jul. 23, 2008.

(30) Foreign Application Priority Data
Aug. 21, 2007 (JP) 2007-214575

(51) Int. Cl. H01L 27/108

(52) U.S. Cl. 257/57; 257/71; 257/E27.084

(57) ABSTRACT

A semiconductor memory device has a plurality of word line provided on a semiconductor region, extending in a row direction, a plurality of bit lines provided in the semiconductor region, extending in a column direction, and a plurality of memory elements provided at intersections between the plurality of word lines and the plurality of bit lines. Each word line provides a first gate electrode in the corresponding memory element. A lower portion of a side surface of each word line in a direction parallel to an extending direction of the word line is perpendicular to a main surface of the semiconductor region. An upper portion of the side surface is inclined so that a width thereof becomes smaller toward a top thereof.

### CROSS REFERENCE TO RELATED APPLICATIONS

This Non-provisional application claims priority under 35 U.S.C. §119(a) on Patent Application No. 2007-214575 filed in Japan on Aug. 21, 2007, the entire contents of which are hereby incorporated by reference.

### BACKGROUND OF THE INVENTION

1. Field of the Invention

The present invention relates to a semiconductor memory device and its manufacturing method, and more particularly, to a non-volatile semiconductor memory device and its manufacturing method.

2. Description of the Related Art

In recent years, various forms of semiconductor memory devices have been proposed. For example, attention has been attracted by a non-volatile semiconductor memory element in which bit lines made of a diffusion layer and word lines made of a conductive layer made of polysilicon or the like are arranged to intersect and electric charges are accumulated in a trap film, since the scale of integration thereof can be easily increased (see, for example, U.S. Pat. No. 6,803,284 and US Published Application No. 2006/0214218).

Hereinafter, a semiconductor memory device according to a first conventional example will be described with reference to the accompanying drawings. FIG. 52 shows a plan view of a memory cell formation region of the conventional semiconductor memory device. FIGS. 53 to 57 show cross-sectional views taken along lines LIII-LIII, LIV-LIV, LV-LV, LVI-LVI and LVII-LVII of FIG. 52, respectively. Note that FIG. 56B is an expanded view of a portion indicated by a reference letter A of FIG. 56A.

As shown in FIGS. 52 and 53, a plurality of isolation regions 104 made of a buried oxide film are formed in an upper portion of a semiconductor substrate 101 made of, for example, silicon. A plurality of source/drain regions (diffusion bit lines) 105 made of an n-type impurity diffusion layer are spaced from each other in one direction. Bit line contact portions 113 connected to the source/drain regions 105 are separated by the isolation regions 104.

As shown in FIGS. 54 and 55, a bit line buried oxide film 109 is formed on each source/drain region 105. A trap film 106 is formed on an active region formed between each source/drain region 105. The trap film 106 is made of a stack of, for example, silicon oxide, silicon nitride and silicon oxide films (so-called ONO film), and has a site where electric charges are trapped.

A word line 110 which provides a gate electrode of each memory cell is formed on each trap film 106. The word line 110 is made of polycrystal silicon into which an n-type impurity (e.g., phosphorus) is introduced, and is formed in a direction that intersects the bit line buried oxide film 109.

As shown in FIG. 56A, a buried insulating film 111 is buried between adjacent word lines 110 formed on the trap film 106. A metal silicide layer 123 is formed on an upper surface of each word line 110 that is exposed from the buried insulating film 111. An interlayer insulating film 112 is formed on each word line 110 in which the metal silicide layer 123 is formed, and each buried insulating film 111.

As shown in FIG. 57, in the bit line contact portion 113, the source/drain region 105 is connected to a contact 114 that penetrates through the interlayer insulating film 112, and is also connected to a bit interconnect 115 made of a metal formed on the interlayer insulating film 112. Note that the bit line contact portion 113 connected to the source/drain region 105 forms the high-concentration impurity diffusion layer 122, and the metal silicide layer 123 is also formed in an upper portion of the high-concentration impurity diffusion layer 122.

Note that, in FIG. 52, the buried insulating film 111, the interlayer insulating film 112, the bit line buried oxide film 109, and the trap film 106 and bit interconnect 115 are not shown.

In the semiconductor memory device of the first conventional example, when the pitch of the word lines 110 is reduced as the level of microfabrication and the scale of integration are enhanced, it is difficult to reduce the height of the word line 110 since electrical characteristics thereof need to be secured, so that the aspect ratio of an interval between adjacent word lines 110 is inevitably increased. Therefore, the following problems arise when the buried insulating film 111 is buried between each word line 110 for electrical separation, and when the metal silicide layer 123 is subsequently formed.

Firstly, as shown in FIG. 56B, when the buried insulating film 111 is buried between each word line 110, a slit-like void 111a occurs between each word line 110, depending on the step coverage property of a material for the buried insulating film 111.

Secondly, when the buried insulating film 111 is etched (etch back) to expose an upper surface of the word line 110, etching proceeds along the slit-like void 111a, so that the void 111a reaches the trap film 106 or the active region below the trap film 106. When the void 111a thus reaches the trap film 106 and further the active region, charge-up or the like occurs in or an unexpected ion injection species reaches the trap film 106 or the active region, so that memory retention characteristics are adversely affected.

In contrast, a semiconductor memory device according to a second conventional example has been proposed in which the occurrence of the void 111a can be suppressed by providing a structure in which, for example, a side surface of the word line (gate electrode) 110 is inclined (see, for example, US Published Application No. 2007/0048993 and R. Koval et al. “Flash ETOX Virtual Ground Architecture: A Future Scaling Direction”, 2005 Symposium on VLSI Technology 11B-1).

In these documents, as shown in FIG. 58A, a side surface of the word line 110 is inclined so that a width thereof becomes narrower toward the top, so that the value of an aspect ratio that is the ratio of the height of the word line 110 to the interval between each word line 110 apparently becomes smaller. Therefore, as shown in FIG. 58B that shows an expanded view of a region B of FIG. 58A, when the buried insulating film 111 is buried between each word line 110, a satisfactory step coverage property is obtained, so that the occurrence of the void 111a is suppressed.

However, the second conventional example has the following problem. Specifically, as shown in FIG. 59A, and FIG. 59B that shows an expanded view of a region C of FIG. 59A, when the word line 110 is subjected to patterning by dry etching or the like, then if the bit line buried oxide film 109 or the isolation region 104 (shallow trench isolation (STI), etc.)) is provided below the word line 110, an etching residue 110c occurs on a sidewall thereof. If the residue 110c short-circuits the word lines 110, the yield significantly decreases.

To solve this problem, etching conditions may be modified so that, for example, etching time is extended, which is a well-known technique. In this case, however, an extraordinary shape, such as a notch or the like, often occurs in a lower portion of the word line (gate electrode) 110. If the buried insulating film 111 is buried in a portion where a notch occurs, a void occurs. Thus, the occurrence of a void is often not suppressed.

Therefore, the method of adjusting etching conditions for the semiconductor memory device of the second conventional example requires formation conditions that need to be highly accurately controlled.

### SUMMARY OF THE INVENTION

In view of the above-described problems, the present invention has been achieved. An object of the present invention is to suppress the occurrence of a void that occurs in an insulating film buried between word lines (gate electrodes) and suppress the occurrence of an etching residue when the word line is fabricated.

To achieve the object, the present invention provides a semiconductor memory device in which an upper portion of a side surface in an extending direction of a word line (gate electrode) is inclined so that a width between each side surface becomes narrower toward the top, while a lower portion of the side surface is formed perpendicular to a bottom surface thereof.

Specifically, a semiconductor memory device according to an aspect of the present invention includes a plurality of word line provided on a semiconductor region, extending in a row direction, a plurality of bit lines provided in the semiconductor region, extending in a column direction, and a plurality of memory elements provided at intersections between the plurality of word lines and the plurality of bit lines. Each of the plurality of word lines provides a first gate electrode in the corresponding one of the plurality of memory elements. A lower portion of a side surface of each word line in a direction parallel to an extending direction of the word line is perpendicular to a main surface of the semiconductor region. An upper portion of the side surface is inclined so that a width thereof becomes smaller toward a top thereof.

According to the semiconductor memory device of the aspect of the present invention, the upper portion of the side surface of each word line in the direction parallel to the extending direction of the word line is inclined so that the width becomes smaller toward the top. Therefore, the value of an aspect ratio of a height of the word line and an interval between each word line is substantially small. Therefore, when a buried material is buried for insulation and separation between each word line, a step coverage property with respect to the word line is satisfactory, so that the occurrence of a void can be suppressed. In addition, since the lower portion of the side surface of each word line is formed perpendicular to the main surface of the semiconductor region, an etching residue due to a material for word line is less likely to occur on a side wall of a bit line buried insulating film made of an impurity diffusion layer or an isolation region (STI, etc.).

In the semiconductor memory device of the aspect of the present invention, each word line preferably includes a multilayer film including a lower-layer film and an upper-layer film provided on the lower-layer film. A side surface of the lower-layer film in the direction parallel to the extending direction of the word line is preferably perpendicular to the main surface of the semiconductor region. A side surface of the upper-layer film in the direction parallel to the extending direction of the word line is preferably inclined so that a width thereof becomes smaller toward a top thereof.

In the semiconductor memory device of the aspect of the present invention, each memory element preferably has a trap film for accumulating electric charges. The trap film serves as a gate insulating film.

In this case, the gate insulating film is preferably a multilayer film that is a stack of a lower-layer silicon oxide film, a charge-accumulating silicon nitride film and an upper-layer silicon oxide film that are successively formed, the lower-layer silicon oxide film being closest to the semiconductor region.

In the semiconductor memory device of the aspect of the present invention, when each word line includes a multilayer film including a lower-layer film and an upper-layer film, the lower-layer film is preferably a floating gate electrode for accumulating electric charges, the upper-layer film is preferably a control gate electrode, and an interelectrode insulating film is preferably provided between the floating gate electrode and the control gate electrode, in the first gate electrode.

In the semiconductor memory device of the aspect of the present invention, each bit line preferably includes an impurity diffusion layer that is selectively provided in an upper portion of the semiconductor region.

In this case, the impurity diffusion layer preferably includes a first impurity diffusion layer, and a second impurity diffusion layer provided around the first impurity diffusion layer.

In this case, an impurity concentration of the first impurity diffusion layer is preferably higher than an impurity concentration of the second impurity diffusion layer.

The semiconductor memory device of the aspect of the present invention preferably further includes a plurality of bit line buried insulating films covering upper portions of the plurality of bit lines. A height of the bit line buried insulating film is preferably the same as a height of the lower portion of the side surface of the word line.

In the semiconductor memory device of the aspect of the present invention, when each word line includes a multilayer film including a lower-layer film and an upper-layer film, the lower-layer film and the upper-layer film are preferably made of polycrystal silicon or amorphous silicon.

In this case, a metal silicide layer is preferably provided in an upper portion of the upper-layer film.

In the semiconductor memory device of the aspect of the present invention, at least the upper-layer film of the word line is preferably a metal film.

The semiconductor memory device of the aspect of the present invention preferably further includes a plurality of bit interconnects provided above the semiconductor region, each bit interconnect being electrically connected to the corresponding bit line via a corresponding contact. A metal silicide layer is preferably provided in a region where the bit line is connected to the contact.

Also, the semiconductor memory device of the aspect of the present invention preferably further includes a logic circuit portion provided in a region excluding the memory elements of the semiconductor region, the logic circuit portion including a transistor having a second gate electrode. The second gate electrode preferably includes a multilayer film having the same configuration as that of the word line including the lower-layer film and the upper-layer film.

A first method for manufacturing a semiconductor memory device according to an aspect of the present invention includes the steps of (a) forming a trap film for holding electric charges on a semiconductor region, (b) forming a first mask film on the trap film, the first mask film having a plurality of opening portions spaced from each other and extending in a column direction, (c) forming a plurality of bit lines in an upper portion of the semiconductor region by introducing an impurity into the semiconductor region using the first mask film, the bit lines extending in a column direction and each including an impurity diffusion layer, (d) burying a first buried insulating film in each opening portion of the first mask film, (e) after the step (d), removing the first mask film, and thereafter, forming a first conductive film on the semiconductor region, (f) forming a second mask film having a plurality of opening portions on the first conductive film, the opening portions being spaced from each other and extending in a row direction, and (g) subjecting the first conductive film to patterning by etching using the second mask film to form a plurality of word lines from the first conductive film, and exposing the first buried insulating film. The step (g) includes a first step of performing etching until an upper surface of the first buried insulating film is exposed, so that a width of an upper portion of a side surface in a direction parallel to an extending direction of each word line becomes larger toward a bottom thereof as the etching proceeds, and a second step of performing patterning by the etching after an upper surface of the first buried insulating film is exposed and until the trap film is exposed, so that a lower portion of the side surface of each word line is perpendicular to a main surface of the semiconductor region.

In the first method, preferably, in the step (b), a portion of the trap film exposed from each opening portion of the first mask film is left, and in the step (c), the impurity is introduced via the trap film into the semiconductor region.

Also, in the first method, preferably, in the step (b), a portion of the trap film exposed from each opening portion of the first mask film is also removed, and in the step (c), the impurity is directly introduced into the semiconductor region.

In the first method, preferably, in the step (e), the first conductive film is a polycrystal silicon film, an amorphous silicon film, a metal film, a multilayer film including a polycrystal silicon film and a silicide film, or a multilayer film including an amorphous silicon film and a silicide film.

The first method preferably further includes (h) after the step (g), forming a second buried insulating film between adjacent ones of the word lines while exposing an upper surface of each word line, and (i) causing the exposed upper surface of each word line to be silicide.

A second method for manufacturing a semiconductor memory device according to an aspect of the present invention includes the steps of (a) forming a trap film for holding electric charges on a semiconductor region, (b) forming a first conductive film on the trap film, (c) forming a first mask film on the first conductive film, the first mask film having a plurality of opening portions spaced from each other and extending in a column direction, (d) selectively removing at least the first conductive film using the first mask film, and thereafter, forming a plurality of bit lines in an upper portion of the semiconductor region by introducing an impurity into the semiconductor region through each opening portion formed in the first mask film and the first conductive film, the bit lines extending in a column direction and each including an impurity diffusion layer, (e) forming a first buried insulating film in each opening portion formed in the first mask film and the first conductive film while exposing the first mask film, (f) after the step (e), removing the first mask film, and thereafter, forming a second conductive film on the first conductive film and the first buried insulating film, (g) forming a second mask film having a plurality of opening portions on the second conductive film, the opening portions being spaced from each other and extending in a row direction, and (h) subjecting the second conductive film and the first conductive film to patterning by etching using the second mask film to form a plurality of word lines from the first conductive film and the second conductive film, and exposing the first buried insulating film. The step (h) includes a first step of etching the second conductive film so that a width of a side surface in a direction parallel to an extending direction of each word line becomes larger toward a bottom thereof as the etching proceeds, and a second step of subjecting the first conductive film to patterning by the etching so that a side surface of each word line is perpendicular to a main surface of the semiconductor region.

In the second method, preferably, in the step (c), a portion of the trap film exposed from each opening portion of the first mask film is left, and in the step (d), the impurity is introduced via the trap film into the semiconductor region.

In the second method, preferably, in the step (c), a portion of the trap film exposed from each opening portion of the first mask film is also removed, and in the step (d), the impurity is directly introduced into the semiconductor region.

In the second method, preferably, in the step (f), the second conductive film is a polycrystal silicon film, an amorphous silicon film, a metal film, a multilayer film including a polycrystal silicon film and a silicide film, or a multilayer film including an amorphous silicon film and a silicide film.

The second method preferably further includes (i) after the step (h), forming a second buried insulating film between adjacent word lines while exposing an upper surface of each word line, and (j) causing the exposed upper surface of each word line to be silicide.

A third method for manufacturing a semiconductor memory device according to an aspect of the present invention includes the steps of (a) forming a tunnel film on a semiconductor region, (b) forming a first conductive film on the tunnel film, (c) forming a first mask film on the first conductive film, the first mask film having a plurality of opening portions spaced from each other and extending in a column direction, (d) selectively removing at least the first conductive film using the first mask film, and thereafter, forming a plurality of bit lines in an upper portion of the semiconductor region by introducing an impurity into the semiconductor region through each opening portion formed in the first mask film and the first conductive film, the bit lines extending in a column direction and each including an impurity diffusion layer, (e) forming a first buried insulating film in each of the plurality of opening portions formed in the first mask film and the first conductive film while exposing the first mask film, (f) after the step (e), removing the first mask film, and thereafter, forming an interelectrode insulating film on the first conductive film and the first buried insulating film, (g) forming a second conductive film on the interelectrode insulating film, (h) forming a second mask film having a plurality of opening portions on the second conductive film, the opening portions being spaced from each other and extending in a row direction, and (i) subjecting the second conductive film, the interelectrode insulating film and the first conductive film to patterning by etching using the second mask film to form a plurality of word lines from the first conductive film, the interelectrode insulating film and the second conductive film, and exposing the first buried insulating film. The step (i) includes a first step of etching the second conductive film so that a width of a side surface in a direction parallel to an extending direction of each word line becomes larger toward a bottom thereof as the etching proceeds, and a second step of subjecting the first conductive film to patterning by the etching so that a side surface of each word line is perpendicular to a main surface of the semiconductor region.

In the third method, preferably, in the step (c), a portion of the tunnel film exposed from each of the plurality of opening portions of the first mask film is left, and in the step (d), the impurity is introduced via the tunnel film into the semiconductor region.

Also, in the third method, preferably, in the step (c), a portion of the tunnel film exposed from each of the plurality of opening portions of the first mask film is also removed, and in the step (d), the impurity is directly introduced into the semiconductor region.

In the third method, preferably, in the step (g), the second conductive film is a polycrystal silicon film, an amorphous silicon film, a metal film, a multilayer film including a polycrystal silicon film and a silicide film, or a multilayer film including an amorphous silicon film and a silicide film.

The third method preferably further includes (j) after the step (i), forming a second buried insulating film between adjacent word lines while exposing an upper surface of each word line, and (k) causing the exposed upper surface of each word line to be silicide.

In the first method, the semiconductor region preferably has a logic circuit formation region. The method preferably further includes, between the steps (a) and (e), (j) selectively forming a gate insulating film on the logic circuit formation region of the semiconductor region. In the step (e), the first conductive film is also preferably formed on the gate insulating film in the logic circuit formation region. In the step (f), a pattern for forming a gate electrode of a transistor is preferably formed from a portion covering the logic circuit formation region of the second mask film. The step (g) preferably includes forming the gate electrode of the transistor in the logic circuit formation region from a portion included in the logic circuit formation region of the first conductive film.

Also, in the second method, the semiconductor region preferably has a logic circuit formation region. The method preferably further includes, between the steps (a) and (b), (k) selectively forming a gate insulating film on the logic circuit formation region of the semiconductor region. In the step (b), the first conductive film is also preferably formed on the gate insulating film in the logic circuit formation region. In the step (f), the second conductive film is also preferably formed on the first conductive film in the logic circuit formation region. In the step (g), a pattern for forming a gate electrode of a transistor is preferably formed from a portion covering the logic circuit formation region of the second mask film. The step (h) preferably includes forming the gate electrode of the transistor in the logic circuit formation region from portions included in the logic circuit formation region of the first conductive film and the second conductive film.

In the third method, the semiconductor region preferably has a logic circuit formation region. The method preferably further includes, between the steps (a) and (b), (l) selectively forming a gate insulating film on the logic circuit formation region of the semiconductor region. In the step (b), the first conductive film is also preferably formed on the gate insulating film in the logic circuit formation region. In the step (g), the second conductive film is also preferably formed on the first conductive film in the logic circuit formation region. In the step (h), a pattern for forming a gate electrode of a transistor is preferably formed from a portion covering the logic circuit formation region of the second mask film. The step (i) preferably includes forming the gate electrode of the transistor in the logic circuit formation region from portions included in the logic circuit formation region of the first conductive film and the second conductive film.

As described above, according to the semiconductor memory device of the present invention and its manufacturing method, bit lines made of a diffusion layer are formed and spaced from each other in a semiconductor region, and word lines (gate electrode) are formed and spaced from each other, intersecting the bit lines. In the semiconductor memory device, a void is suppressed from occurring in an insulating film between each word line, and etching residue due to the word line is suppressed.

### BRIEF DESCRIPTION OF THE DRAWINGS

FIG. 1 is a plan view showing a memory cell region in a semiconductor memory device according to a first embodiment of the present invention.

FIG. 2 is a cross-sectional view taken along line II-II of FIG. 1.

FIG. 3 is a cross-sectional view taken along line of FIG. 1.

FIG. 4 is a cross-sectional view taken along line IV-IV of FIG. 1.

FIG. 5 is a cross-sectional view taken along line V-V of FIG. 1.

FIG. 6 is a cross-sectional view taken along line VI-VI of FIG. 1.

FIGS. 7A to 7C are cross-sectional views showing a method for manufacturing the semiconductor memory of the first embodiment of the present invention in the order in which the device is manufactured.

FIGS. 8A to 8C are cross-sectional views showing the method for manufacturing the semiconductor memory of the first embodiment of the present invention in the order in which the device is manufactured.

FIGS. 9A to 9C are cross-sectional views showing the method for manufacturing the semiconductor memory of the first embodiment of the present invention in the order in which the device is manufactured.

FIGS. 10A to 10C are cross-sectional views showing the method for manufacturing the semiconductor memory of the first embodiment of the present invention in the order in which the device is manufactured.

FIGS. 11A and 11B are cross-sectional views showing the method for manufacturing the semiconductor memory of the first embodiment of the present invention in the order in which the device is manufactured.

FIGS. 12A and 12B are cross-sectional views showing the method for manufacturing the semiconductor memory of the first embodiment of the present invention in the order in which the device is manufactured.

FIGS. 13A and 13B are cross-sectional views showing the method for manufacturing the semiconductor memory of the first embodiment of the present invention in the order in which the device is manufactured.

FIGS. 14A and 14B are cross-sectional views showing the method for manufacturing the semiconductor memory of the first embodiment of the present invention in the order in which the device is manufactured.

FIG. 15 is a plan view showing a memory cell region in a semiconductor memory device according to a second embodiment of the present invention.

FIG. 16 is a cross-sectional view taken along line XVI-XVI of FIG. 15.

FIG. 17 is a cross-sectional view taken along line XVII-XVII of FIG. 15.

FIG. 18 is a cross-sectional view taken along line XVIII-XVIII of FIG. 15.

FIGS. 19A to 19C are cross-sectional views showing a method for manufacturing the semiconductor memory of the second embodiment of the present invention in the order in which the device is manufactured.

FIGS. 20A to 20C are cross-sectional views showing the method for manufacturing the semiconductor memory of the second embodiment of the present invention in the order in which the device is manufactured.

FIGS. 21A and 21B are cross-sectional views showing the method for manufacturing the semiconductor memory of the second embodiment of the present invention in the order in which the device is manufactured.

FIGS. 22A and 22B are cross-sectional views showing the method for manufacturing the semiconductor memory of the second embodiment of the present invention in the order in which the device is manufactured.

FIGS. 23A and 23B are cross-sectional views showing the method for manufacturing the semiconductor memory of the second embodiment of the present invention in the order in which the device is manufactured.

FIGS. 24A and 24B are cross-sectional views showing the method for manufacturing the semiconductor memory of the second embodiment of the present invention in the order in which the device is manufactured.

FIGS. 25A and 25B are cross-sectional views showing the method for manufacturing the semiconductor memory of the second embodiment of the present invention in the order in which the device is manufactured.

FIGS. 26A and 26B are cross-sectional views showing the method for manufacturing the semiconductor memory of the second embodiment of the present invention in the order in which the device is manufactured.

FIG. 27 is a plan view showing a memory cell region in a semiconductor memory device according to a third embodiment of the present invention.

FIG. 28 is a cross-sectional view taken along line XXVIII-XXVIII of FIG. 27.

FIG. 29 is a cross-sectional view taken along line XXIX-XXIX of FIG. 27.

FIG. 30 is a cross-sectional view taken along line XXX-XXX of FIG. 27.

FIG. 31 is a cross-sectional view taken along line XXXI-XXXI of FIG. 27.

FIGS. 32A to 32C are cross-sectional views showing a method for manufacturing the semiconductor memory of the third embodiment of the present invention in the order in which the device is manufactured.

FIGS. 33A to 33C are cross-sectional views showing the method for manufacturing the semiconductor memory of the third embodiment of the present invention in the order in which the device is manufactured.

FIGS. 34A and 34B are cross-sectional views showing the method for manufacturing the semiconductor memory of the third embodiment of the present invention in the order in which the device is manufactured.

FIGS. 35A and 35B are cross-sectional views showing the method for manufacturing the semiconductor memory of the third embodiment of the present invention in the order in which the device is manufactured.

FIGS. 36A and 36B are cross-sectional views showing the method for manufacturing the semiconductor memory of the third embodiment of the present invention in the order in which the device is manufactured.

FIGS. 37A and 37B are cross-sectional views showing the method for manufacturing the semiconductor memory of the third embodiment of the present invention in the order in which the device is manufactured.

FIGS. 38A and 38B are cross-sectional views showing the method for manufacturing the semiconductor memory of the third embodiment of the present invention in the order in which the device is manufactured.

FIGS. 39A and 39B are cross-sectional views showing the method for manufacturing the semiconductor memory of the third embodiment of the present invention in the order in which the device is manufactured.

FIGS. 40A to 40C are cross-sectional views showing a method for manufacturing a semiconductor memory according to a fourth embodiment of the present invention in the order in which the device is manufactured.

FIGS. 41A to 41C are cross-sectional views showing the method for manufacturing the semiconductor memory of the fourth embodiment of the present invention in the order in which the device is manufactured.

FIGS. 42A and 42B are cross-sectional views showing the method for manufacturing the semiconductor memory of the fourth embodiment of the present invention in the order in which the device is manufactured.

FIGS. 43A to 43C are cross-sectional views showing the method for manufacturing the semiconductor memory of the fourth embodiment of the present invention in the order in which the device is manufactured.

FIGS. 44A to 44C are cross-sectional views showing a method for manufacturing a semiconductor memory according to a fifth embodiment of the present invention in the order in which the device is manufactured.

FIGS. 45A to 45C are cross-sectional views showing the method for manufacturing the semiconductor memory of the fifth embodiment of the present invention in the order in which the device is manufactured.

FIGS. 46A and 46B are cross-sectional views showing the method for manufacturing the semiconductor memory of the fifth embodiment of the present invention in the order in which the device is manufactured.

FIGS. 47A to 47C are cross-sectional views showing the method for manufacturing the semiconductor memory of the fifth embodiment of the present invention in the order in which the device is manufactured.

FIGS. 48A to 48C are cross-sectional views showing a method for manufacturing a semiconductor memory according to a sixth embodiment of the present invention in the order in which the device is manufactured.

FIGS. 49A to 49C are cross-sectional views showing the method for manufacturing the semiconductor memory of the sixth embodiment of the present invention in the order in which the device is manufactured.

FIGS. 50A and 50B are cross-sectional views showing the method for manufacturing the semiconductor memory of the sixth embodiment of the present invention in the order in which the device is manufactured.

FIGS. 51A to 51C are cross-sectional views showing the method for manufacturing the semiconductor memory of the sixth embodiment of the present invention in the order in which the device is manufactured.

FIG. 52 is a plan view showing a memory cell region in a semiconductor memory device according to a first conventional example.

FIG. 53 is a cross-sectional view taken along line LIII-LIII of FIG. 52.

FIG. 54 is a cross-sectional view taken along line LIV-LIV of FIG. 52.

FIG. 55 is a cross-sectional view taken along line LV-LV of FIG. 52.

FIG. 56A is a cross-sectional view taken along line LVI-LVI of FIG. 52.

FIG. 56B is an expanded cross-sectional view of a region A of FIG. 56A.

FIG. 57 is a cross-sectional view taken along line LVII-LVII of FIG. 52.

FIGS. 58A and 58B show a memory cell region in a semiconductor memory device according to a second conventional example, FIG. 58A being a cross-sectional view corresponding to LVI-LVI of FIG. 52, and FIG. 58B being an expanded cross-sectional view of a region B of FIG. 58A.

FIGS. 59A and 59B show the memory cell region in the semiconductor memory device of the second conventional example, FIG. 59A being a cross-sectional view corresponding to LV-LV of FIG. 52, and FIG. 59B being an expanded cross-sectional view of a region C of FIG. 59A.

### DETAILED DESCRIPTION OF THE PREFERRED EMBODIMENTS

### First Embodiment

A first embodiment of the present invention will be described with reference to the accompanying drawings.

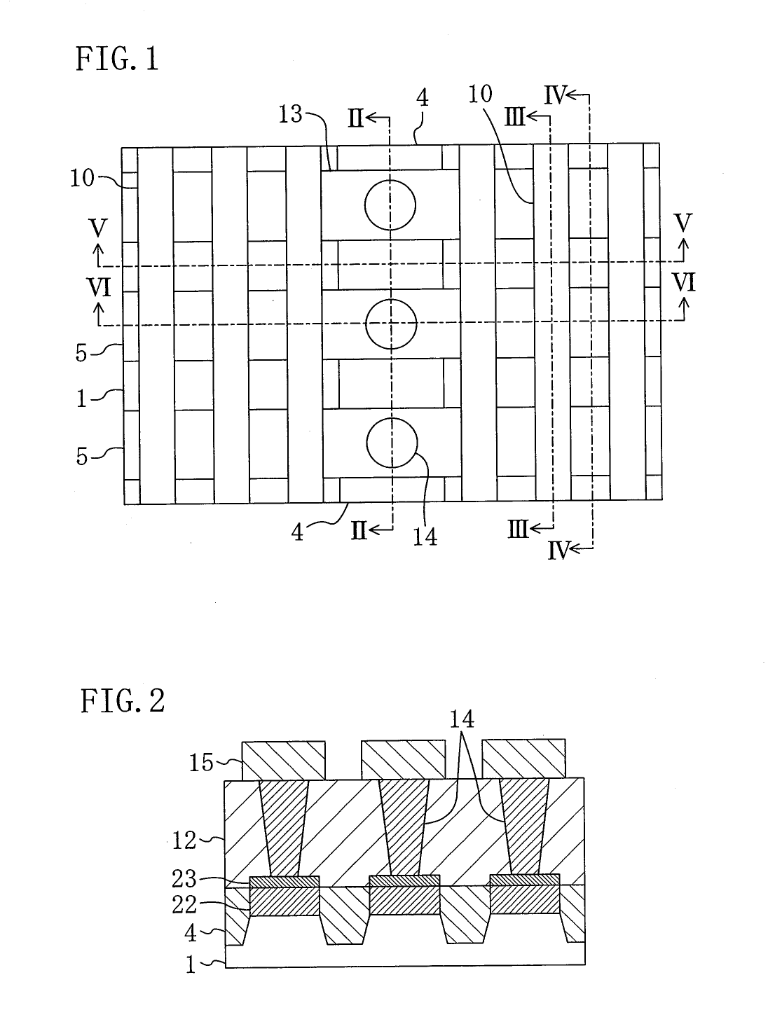

FIG. 1 shows a plan view of a memory cell region in a semiconductor memory device according to a first embodiment of the present invention. FIGS. 2 to 6 show cross-sectional views taken along lines II-II, III-III, IV-IV, V-V and VI-VI of FIG. 1, respectively.

As shown in FIGS. 1 and 2, a plurality of isolation regions 4 (e.g., STI) made of a buried oxide film are formed in an upper portion of a semiconductor substrate 1 made of, for example, silicon (Si). A plurality of source/drain regions 5 made of an n-type impurity diffusion layer that function as diffusion bit lines are formed in one direction in an upper portion of the semiconductor substrate 1. Bit line contact portions 13 connected to the source/drain regions 5 are separated from each other by the isolation regions 4.

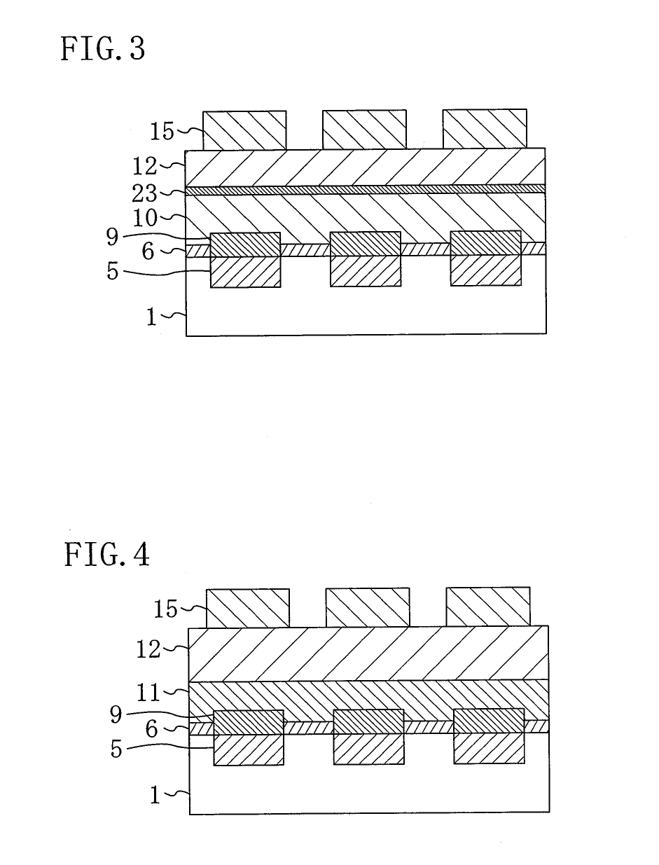

As shown in FIGS. 3 and 4, a bit line buried oxide film 9 is formed on each source/drain region 5. A trap film 6 is formed on an active region formed between each source/drain region 5. The trap film 6 is made of a stack of, for example, silicon oxide, silicon nitride and silicon oxide films (so-called ONO film), and has a site where electric charges are trapped.

A word line 10 which constitutes a gate electrode of each memory cell is formed on each trap film 6. The word line 110 is made of polycrystal silicon into which an n-type impurity (e.g., phosphorus (P)) is introduced, and is formed in a direction that intersects the bit line buried oxide film 9.

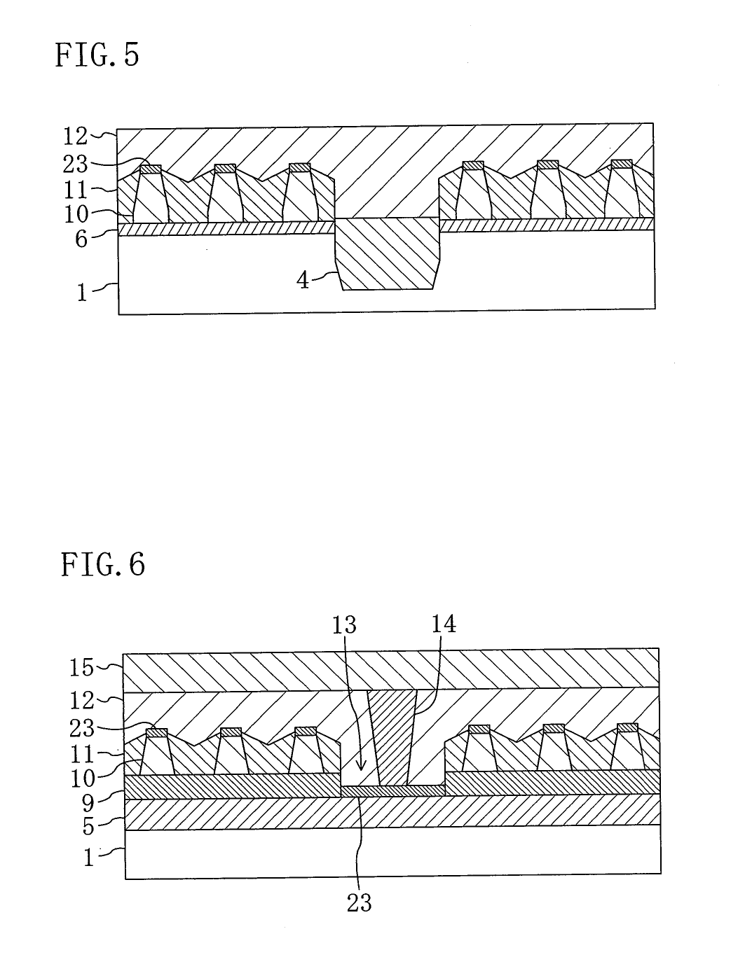

As shown in FIGS. 5 and 6, the word line (gate electrode) 10 of the first embodiment has a side surface in a direction (perpendicular to the surface of the drawing paper) parallel to a direction along which the word line 10 extends. A lower portion of the side surface is perpendicular to a main surface of the semiconductor substrate 1, and an upper portion of the side surface is inclined so that the word line 10 becomes narrower toward the top (e.g., a forward taper shape). Here, as can be seen from FIGS. 5 and 6, up to the height of the bit line buried oxide film 9 corresponds to the lower portion of the word line 10.

As shown in FIG. 5, a buried insulating film 11 is buried between adjacent word lines 10 formed on the trap film 6. A metal silicide layer 23 made of, for example, cobalt (Co), nickel (Ni) or the like is formed on an upper surface of each word line 10 that is exposed from the buried insulating film 11. An interlayer insulating film 12 is formed on each word line 10 in which the metal silicide layer 23 is formed, and each buried insulating film 11.

As shown in FIG. 6, in the bit line contact portion 13, the source/drain region 5 that is a diffusion bit line is connected to a contact 14 that penetrates through the interlayer insulating film 12, and a bit interconnect 15 that is made of a metal including, for example, aluminum (Al) or copper (Cu) as a major component and is formed on the interlayer insulating film 12. Note that a reason why the bit interconnect 15 made of the metal is provided in parallel with the source/drain region 5 is that the bit interconnect 15 having a lower resistance can enable faster access to the source/drain region 5 made of the impurity diffusion layer and hence the memory cell.

The bit line contact portion 13 connected to the source/drain region 5 is made of a high-concentration impurity diffusion layer 22. The metal silicide layer 23 is also formed in an upper portion of the high-concentration impurity diffusion layer 22.

Note that the buried insulating film 11, the interlayer insulating film 12, the bit line buried oxide film 9, the trap film 6, and the bit interconnect 15 are not shown in FIG. 1.

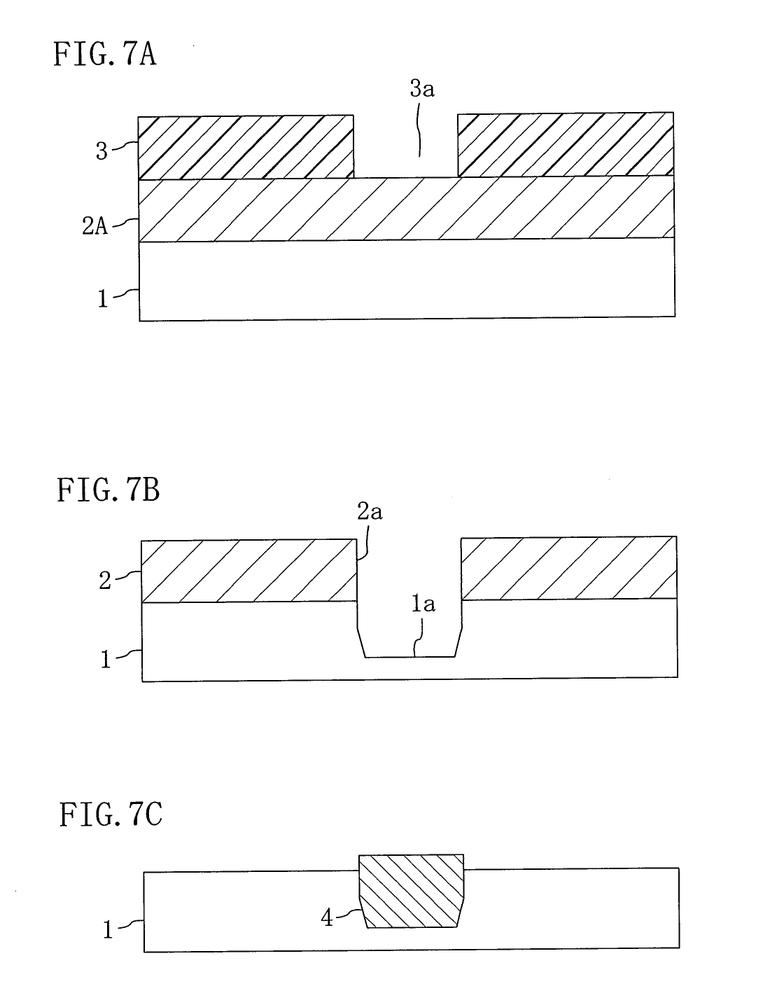

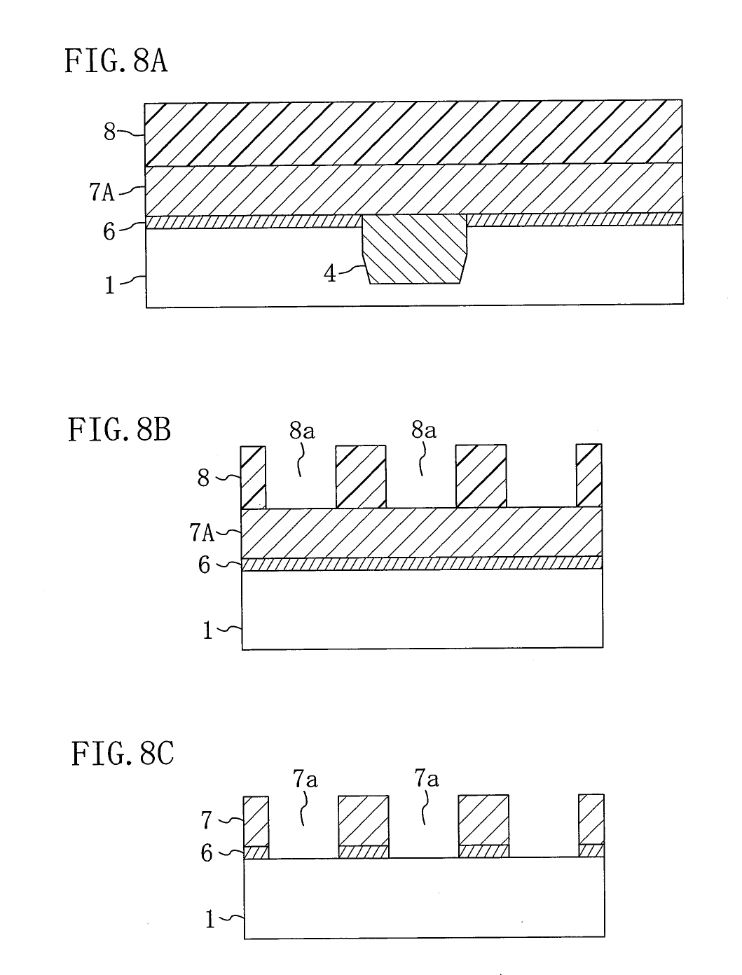

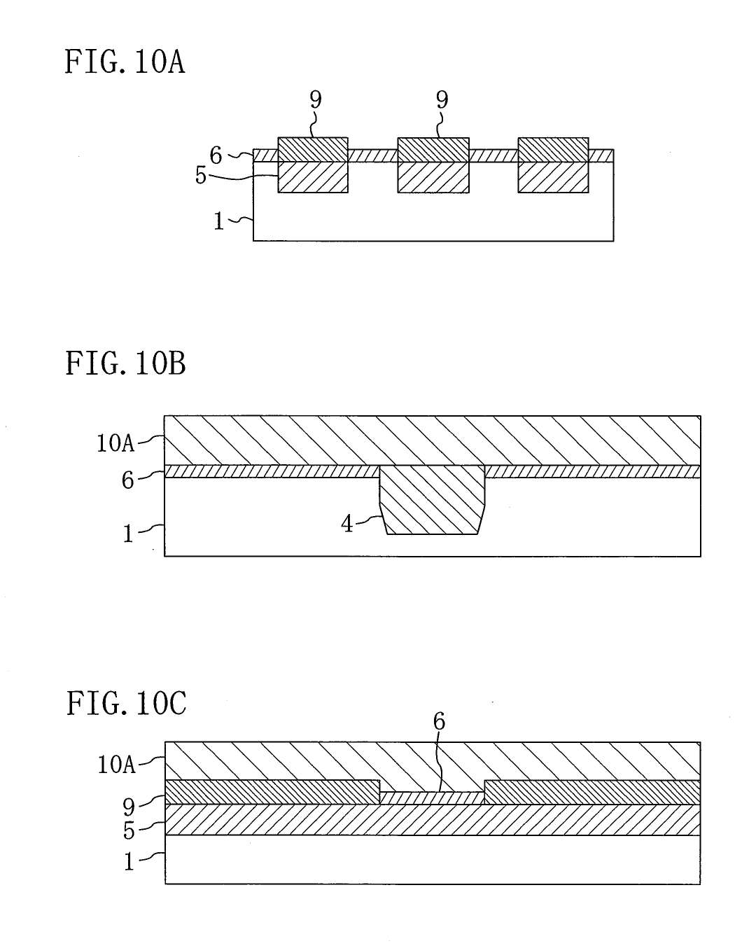

Hereinafter, a method for manufacturing the thus-configured semiconductor memory device will be described with reference to FIGS. 7 to 14. Note that FIGS. 7A to 14B show cross-sectional views each taken along any one of lines of FIG. 1. Specifically, FIGS. 7A to 8A, 10B, 11A, 12A, 13A and 14A show cross-sectional views taken along line V-V of FIG. 1. FIGS. 8B to 10A show cross-sectional views taken along line III-III of FIG. 1, and FIGS. 10C, 11B, 12B, 13B and 14B show cross-sectional views taken along line VI-VI of FIG. 1.

Initially, as shown in FIG. 7A, a first mask formation film 2A made of, for example, silicon nitride having a thickness of about 80 nm to 300 nm is formed on a main surface of the semiconductor substrate 1. Next, a first resist film 3 is applied on the first mask formation film 2A. Thereafter, an opening portion 3a for formation of an isolation region is formed in the first resist film 3 by lithography.

Next, as shown in FIG. 7B, the first mask formation film 2A is etched by dry etching or the like using the first resist film 3 to form, from the first mask formation film 2A, a first mask film 2 having an opening portion 2a to which the opening portion 3a of the first resist film 3 is transferred. Next, the first resist film 3 is removed before the semiconductor substrate 1 is etched by dry etching or the like using the first mask film 2 to form a groove portion 1a in an upper portion of the semiconductor substrate 1.

Next, as shown in FIG. 7C, the groove portion 1a of the semiconductor substrate 1 is filled with an insulating film made of, for example, silicon oxide. An upper surface of the filling silicon oxide is planarized by chemical mechanical polishing to form the isolation region 4 made of STI or the like.

Next, as shown in FIG. 8A, the trap film 6, which is an ONO film having a film thickness of 20 nm and has a site where electric charges are trapped, is deposited on an entire surface including the isolation regions 4 of the semiconductor substrate 1. Next, a second mask formation film 7A made of silicon nitride having a film thickness of about 50 nm to 200 nm is deposited by, for example, chemical vapor deposition (CVD). Further, a second resist film 8 is applied on the second mask formation film 7A.

Next, as shown in FIG. 8B, opening patterns 8a each having an opening for a source/drain formation region is formed in the second resist film 8 by lithography. Here, the opening has a width of 100 nm, which is a width of the source/drain region 5, i.e., a width of the diffusion bit line. On the other hand, the second resist film 8 has a line width of 150 nm, and this line width corresponds to a channel width of a memory cell transistor.

Next, as shown in FIG. 8C, the second mask formation film 7A is etched by dry etching or the like using the second resist film 8 to form, from the second mask formation film 7A, a second mask film 7 having opening portions 7a to which the opening patterns 8a of the second resist film 8 are transferred. Next, the trap film 6 that is exposed from the opening portion 7a of the second mask film 7 is removed. Note that since the trap film 6 has a film thickness of as small as 20 nm, the trap film 6 may not be removed and may be used as a protection film for the semiconductor substrate 1 during ion implantation.

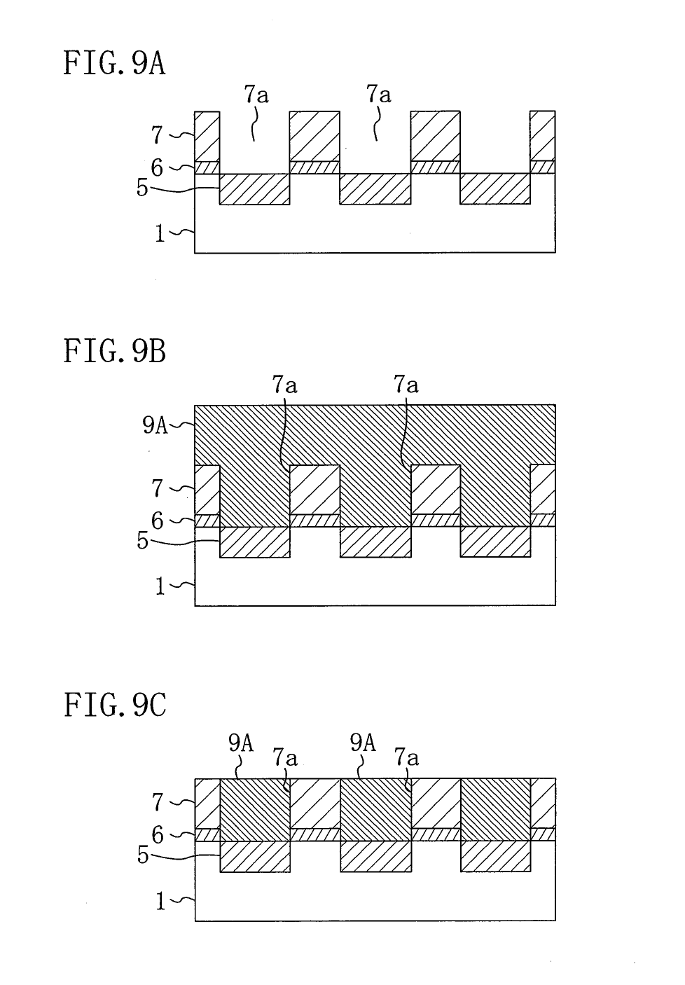

Next, as shown in FIG. 9A, ion implantation is performed once or twice or more using the second mask film 7 under conditions such that, for example, arsenic (As), which is an n-type impurity, is used, the acceleration energy is 5 keV to 200 keV, and the dose is 1×10¹⁴ cm⁻² to 1×10¹⁷ cm⁻², so that the source/drain regions 5 each made of an n-type impurity diffusion layer are formed.

Next, as shown in FIG. 9B, a silicon oxide film 9A is deposited by, for example, high-density plasma chemical vapor deposition (HDP-CVD), low-pressure chemical vapor deposition (LP-CVD) or the like, so that at least each opening portion 7a of the second mask film 7 is buried.

Next, as shown in FIG. 9C, the silicon oxide film 9A is removed by, for example, CMP, etch back, or the like, leaving portions thereof buried in the opening portions 7a of the second mask film 7.

Next, as shown in FIG. 10A, only the second mask film 7 is selectively removed by wet etching, etch back, or the like. Thereby, the trap film 6 is exposed while the bit line buried oxide film 9 is formed of the silicon oxide film 9A. Here, a height of the bit line buried oxide film 9 is adjusted to, for example, 50 nm by wet etching, etch back or the like before or after the removal of the second mask film 7.

Next, as shown in FIGS. 10B and 10C, a polycrystal silicon film 10A that is doped with phosphorus (P), which is an n-type impurity, to about 1×10¹⁸ cm⁻³ to 1×10²² cm⁻³, is deposited on the trap film 6 and the bit line buried oxide film 9 by, for example, LP-CVD.

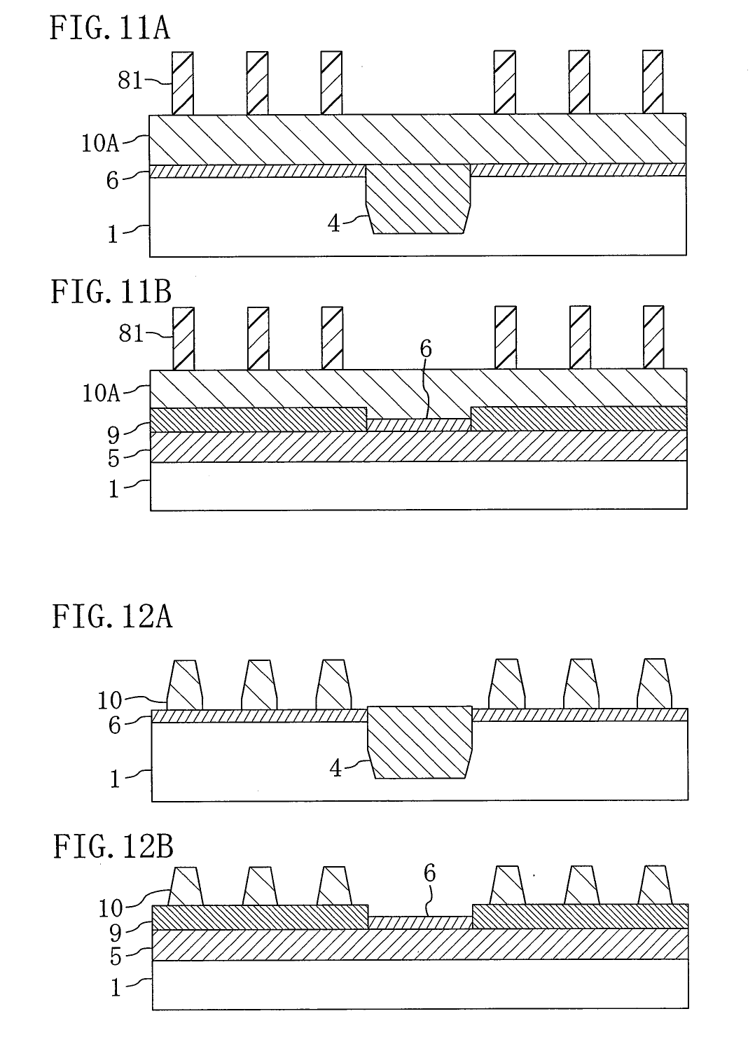

Next, as shown in FIGS. 11A and 11B, a third resist film 81 having a wiring pattern for forming a plurality of word lines is formed in a direction that intersects the source/drain formation region, on the polycrystal silicon film 10A by lithography.

Next, as shown in FIGS. 12A and 12B, the word lines (gate electrodes) 10 made of the polycrystal silicon film 10A are formed by subjecting the polycrystal silicon film 10A to patterning by dry etching using the third resist film 81.

In this case, dry etching is performed so that the side surface in the direction parallel to the extending direction of each word line 10 has an angle of, for example, about 84°±4°, that is smaller than 90°, with respect to the semiconductor substrate 1 (first step). Next, when a height of a lower end portion (deepest portion) of the etched polycrystal silicon film 10A reaches substantially the same height of the bit line buried oxide film 9, dry etching is performed so that the side surface in the direction parallel to the extending direction of each word line 10 has an angle of, for example, about 90°±1° with respect to the semiconductor substrate 1, thereby exposing the trap film 6 between each word line 10 (second step). Note that it is known that etching conditions are modified or switched while monitoring a film thickness during etching (see, for example, Japanese Unexamined Patent Application Publication No. H05-259127).

The method for inclining the side surface of the polycrystal silicon film 10A can be modified by adjusting a pressure or a gas composition during etching, the amount or depth of ions implanted into the polycrystal silicon film 10A, or an annealing time during which ions are diffused in the polycrystal silicon film 10A.

More specifically, the etching conditions for inclining the side surface of the polycrystal silicon film 10A are specifically determined by changing the set values of etching parameters, depending on the required final angle of the side surface. Here, for example, conditions for setting the angle of the side surface of the word line 10 to be 84° are such that, in an inductively coupled high-density plasma etching apparatus, the etching gas species are chloride (Cl₂), hydrogen bromide (HBr), chloride tetrafluoride (CF₄), and oxygen (O₂), and their flow rates are 50 ml/min, 175 ml/min, 35 ml/min, and 3.5 ml/min, respectively. In addition, the pressure is 5×133.3 mPa (=5 mTorr), the RF power of the upper electrode is set to be 600 W, the RF power of the lower electrode is set to be 125 V, and the temperature of the lower electrode is set to be 45° C.

Also, for example, in order to adjust the angle of the side surface of the word line 10 to 88°, the pressure is set to be 10×133.3 mPa (=10 mTorr) and the overall flow rate of the etching gas is set to be double.

The implantation amount and implantation energy of an impurity ion and annealing conditions are set so that the word line 10 finally has an appropriate resistance value. The angle of the side surface can also be adjusted by setting each parameter so that the profile of an ion implantation species becomes nonuniform when etching is performed. In this case, the final profile of the implantation species is caused to become uniform by annealing after implantation to the source/drain, and therefore, the profile of the implantation species does not need to be uniform during etching.

For example, conditions for causing the side surface of the word line 10 to have an angle of 86° are such that phosphorus (P) ions are implanted at an acceleration energy of 15 keV and in a dose of 1×10¹⁴ cm⁻², followed by rapid thermal annealing (RTA) at 700° C. for 30 seconds. Also, for example, conditions for causing the side surface of the word line 10 to have an angle of 88° are such that RTA is performed at 850° C. for 30 seconds. Alternatively, the profile of the ion implantation species may be changed by setting implantation energy to be 35 keV.

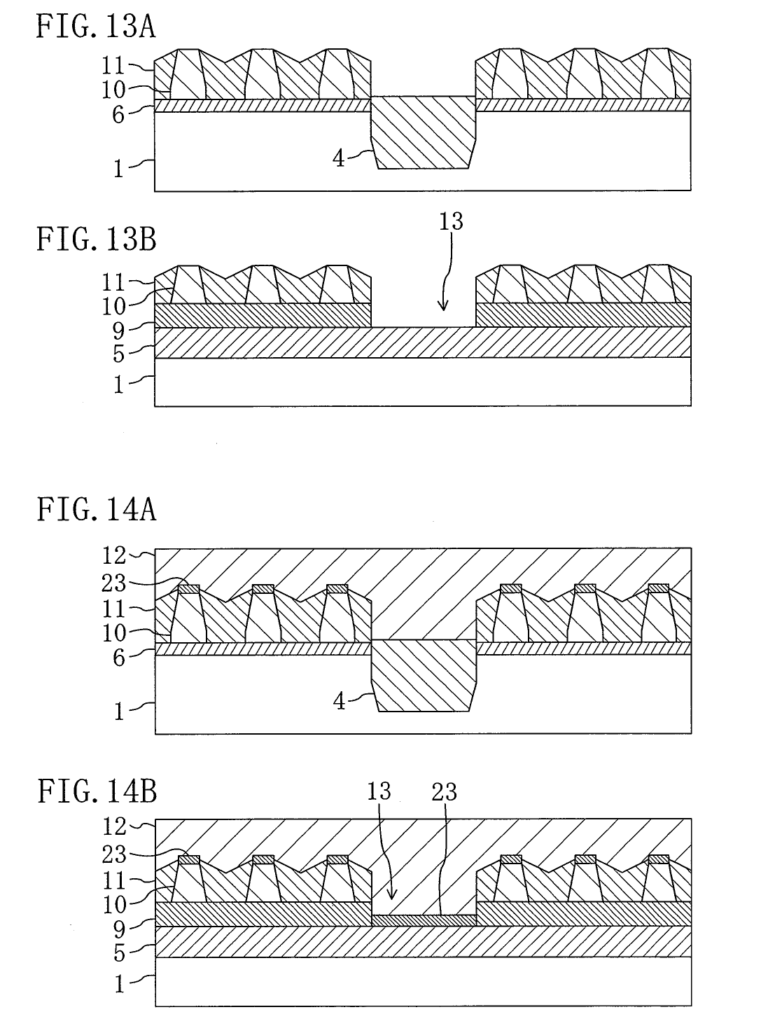

Next, as shown in FIGS. 13A and 13B, the third resist film 81 is removed before the buried insulating film 11 made of silicon oxide or silicon nitride is deposited by, for example, LP-CVD to fill an interstice between each word line 10. In this case, the upper portions of the side surfaces of adjacent word lines 10 become wider toward the top as described above. Therefore, substantially no void occurs in the buried insulating film 11. Next, the buried insulating film 11 on the upper surfaces of the word lines 10 and the bit line contact portion 13 is removed by etch back, leaving the buried insulating film 11 on the side surfaces of the word lines 10.

Next, as shown in FIGS. 14A and 14B, a metal film made of cobalt, nickel or the like is deposited on an entire surface of the semiconductor substrate 1 by, for example, vacuum vapor deposition or the like. Thereafter, a heat treatment is performed to form the metal silicide layer 23 in upper portions of each word line 10 and each bit line contact portion 13. Next, the interlayer insulating film 12 made of silicon oxide is deposited on an entire surface of the semiconductor substrate 1 by, for example, HDP-CVD, atmospheric pressure chemical vapor deposition (AP-CVD), plasma enhanced chemical vapor deposition (PE-CVD), or the like. Thereafter, an upper surface of the interlayer insulating film 12 is planarized by, for example, CMP, dry etch back or the like.

Subsequently, as shown in FIGS. 2 and 6, a connection hole is formed so as to expose the bit line contact portion 13 of each source/drain region 5 formed in the upper portion of the semiconductor substrate 1. A metal monolayer film or a metal multilayer film made of, for example, tungsten (W), a tungsten compound, titanium (Ti), a titanium compound (titanium nitride (TiN), etc.) or the like is deposited on an entire surface of the interlayer insulating film 12, burying each connection hole, so that each contact 14 is formed. Next, a conductive film for formation of a bit interconnect is deposited on the interlayer insulating film 12, and the deposited conductive film is subjected to patterning so as to be electrically connected to each contact 14. Each bit interconnect 15 is thus formed from the conductive film.

According to the first embodiment, the side surface of each word line (gate electrode) 10 in a direction parallel to the extending direction of the word line 10 has the upper and lower portions having different angles. Specifically, the lower portion of the side surface of the word line 10 is perpendicular to the main surface of the semiconductor substrate 1, so that the side surface of the bit line buried oxide film 9 having substantially the same height as that of the lower portion having the perpendicular side surface of the word line 10 is also perpendicular to the main surface of the semiconductor substrate 1. Therefore, an etching residue does not occur on the side surface of the bit line buried oxide film 9. In contrast, the upper portion of the side surface of each word line 10 is inclined so that an interval between adjacent side surfaces becomes wider toward the top. Therefore, a void is unlikely to occur when the buried insulating film 11 is formed and buried between each word line 10.

Thus, in the first embodiment, as is different from the conventional art, a void does not occur in the buried insulating film 11 that is formed between each word line (gate electrode) 10 to insulate and separate the word lines 10, and also, an etching residue does not occur on the side surface of the bit line buried oxide film 9. Therefore, microfabrication of the semiconductor memory device can be achieved with a satisfactory yield.

Although it has been assumed in the first embodiment that the second mask film 7 for formation of the source/drain region 5 is made of silicon nitride, the second mask film 7 may be an insulating film made of a silicon compound, such as silicon oxide or the like, instead of silicon nitride. Also, when the source/drain region 5 is formed, a resist material may be used as a mask instead of a mask film made of a silicon compound.

It has also been assumed in the first embodiment that the trap film 6 having a site where electric charges are trapped is a multilayer film made of three films, i.e., silicon oxide, silicon nitride and silicon oxide films. Instead of this, a monolayer film made of silicon oxynitride, a monolayer film made of silicon nitride, a two-layer film including silicon oxide and silicon nitride films successively formed (i.e., the silicon oxide film closer to the semiconductor substrate 1), or a five-layer film including silicon oxide, silicon nitride, silicon oxide, silicon nitride and silicon oxide films successively deposited may be used.

Although it has also been assumed as an example in the first embodiment that the trap film 6 has a film thickness of 20 nm, the film thickness may be adjusted within 10 nm to 30 nm as appropriate so that transistor characteristics are optimized.

Although it has also been assumed as an example in the first embodiment that the bit line buried oxide film 9 has a height of 50 nm, the height may be adjusted within 20 nm to 100 nm as appropriate so that a leakage current between the word line 10 and the source/drain region 5 is optimized.

Although it has also been assumed as an example in the first embodiment that the n-type impurity diffusion layer included in the source/drain region 5 has a width of 100 nm, the width may be adjusted within 50 nm to 300 nm as appropriate by optimizing transistor characteristics.

It has been assumed in the first embodiment that a resist material (third resist film 81) is used as a mask for dry etching with respect to the polycrystal silicon film 10A included in the word line 10. For a high scale of integration, a high etching selectivity is assumed to be required. In such a case, a mask film made of silicon oxide or silicon nitride may be used, or alternatively, a multilayer mask including these films and a resist material may be used.

Although it has also been assumed in the first embodiment that the step of performing dry etching with respect to the polycrystal silicon film 10A includes switching the step when the height of the side surface to be inclined of each word line 10 becomes the same as the height of the bit line buried oxide film 9, the present invention is not limited to this. Specifically, even if etching may be switched within about ±30 nm from the height of the bit line buried oxide film 9, it is possible to remove etching residue.

Although it has also been assumed in the first embodiment that the polycrystal silicon film 10A included in the word line 10 is formed by depositing doped polysilicon, non-doped polycrystal silicon that is not doped with an impurity may be deposited before being doped by impurity implantation.

Also, the polycrystal silicon film 10A included in the word line 10 is only for illustrative purposes. Instead of polycrystal silicon, a monolayer film made of amorphous silicon, a high-melting point metal having a melting point of 600° C. or more (tantalum (Ta), titanium (Ti), etc.), a metal compound, or a metal silicide, or a multilayer film thereof may be used. Alternatively, the polycrystal silicon film 10A of the word line 10 may be changed to silicide using a metal.

Although it has also been assumed as an example in the first embodiment that the buried insulating film 11 buried between each word line 10 is a silicon oxide film or a silicon nitride film formed by LP-CVD, the present invention is not limited to this. Specifically, any insulating film that has a satisfactory step coverage property and can be formed by a method without plasma may be used. Note that an insulating film that is formed by AP-CVD and hence needs to be subsequently baked at high temperature is difficult to handle and requires highly precise conditions for film formation and baking.

Although it has also been assumed in the first embodiment that a memory element whose source/drain region 5 is of n type is used, a p-type memory element may be used.

Also, in the first embodiment, a side surface and a bottom surface of the n-type impurity diffusion layer included in each source/drain region 5 may be covered by a p-type impurity diffusion layer having a lower impurity concentration than that of the n-type impurity diffusion layer. With this structure, the p-type impurity diffusion layer can suppress a short channel effect that is caused by diffusion of an impurity of the n-type impurity diffusion layer. Therefore, an interval between a pair of source/drain regions 5 can be reduced, i.e., the gate length can be reduced, so that the scale of integration of the semiconductor memory device can be further increased.

### Second Embodiment

Hereinafter, a second embodiment of the present invention will be described with reference to the drawings. Here, only a difference(s) from the semiconductor memory device of the first embodiment of the present invention will be described. Therefore, the same constituents as those of FIGS. 1 to 6 are indicated by the same reference numerals.

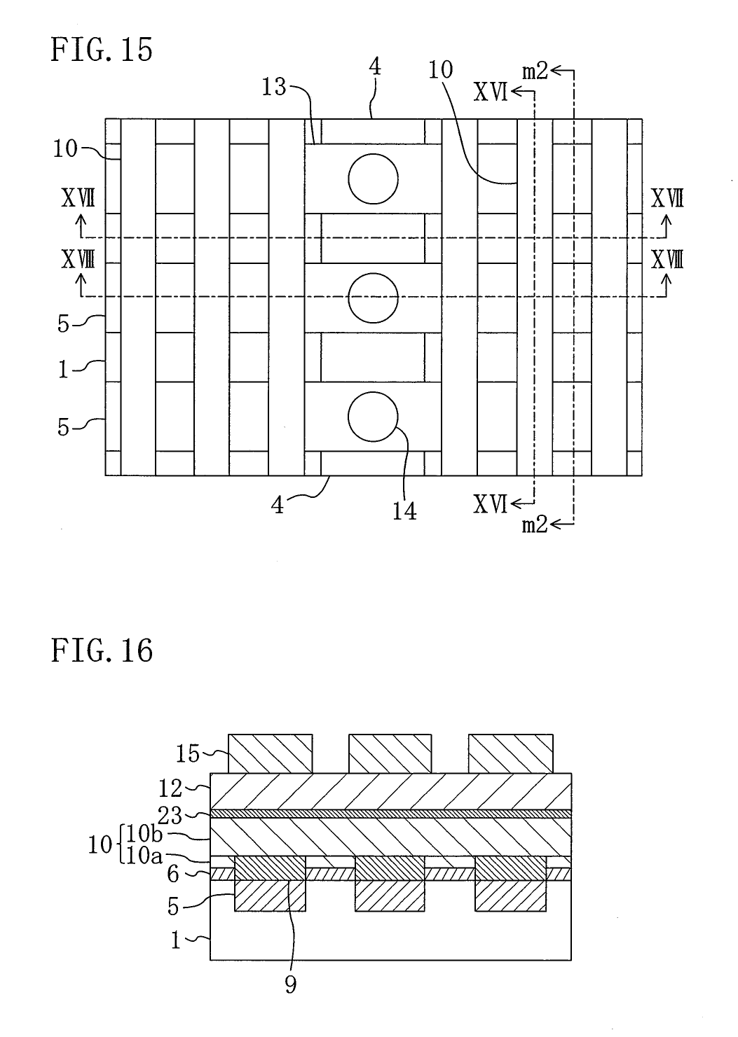

FIG. 15 shows a plan view of a memory cell region in the semiconductor memory device of the second embodiment of the present invention. FIGS. 16 to 18 show cross-sectional views taken along lines XVI-XVI, XVII-XVII and XVIII-XVIII of FIG. 15, respectively.

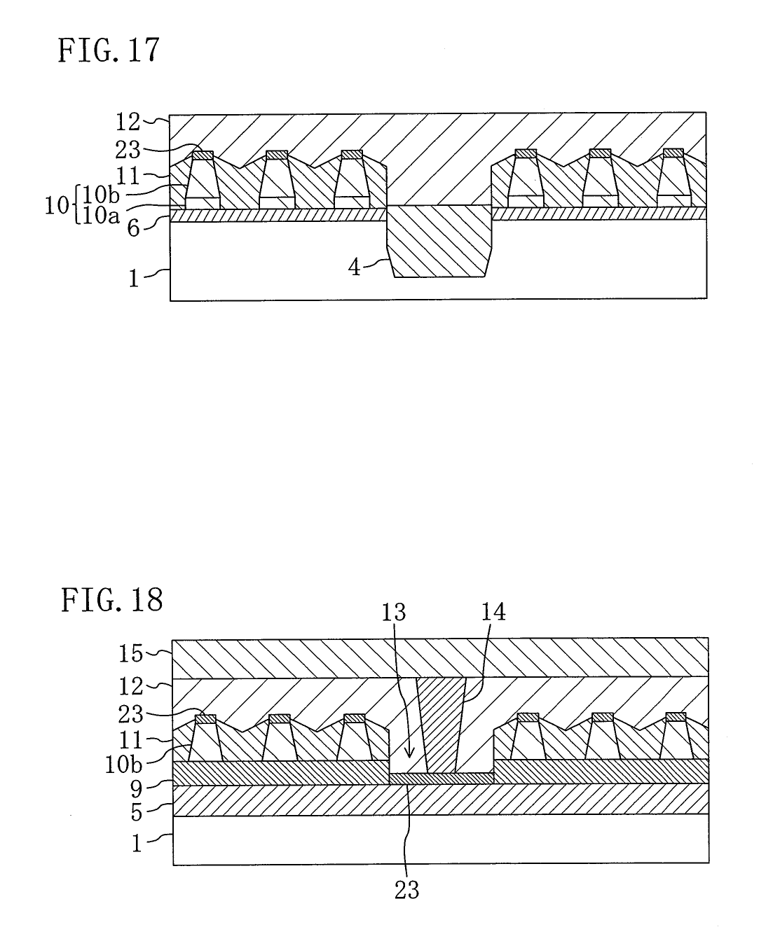

As shown in FIGS. 16 and 17, a word line (gate electrode) 10 of the semiconductor memory device of the second embodiment includes a lower word line 10a and an upper word line 10b. The lower word line 10a has a side surface in a direction parallel to an extending direction of the word line 10, the side surface being perpendicular to a main surface of a semiconductor substrate 1. The upper word line 10b is formed on the lower word line 10a, and has a side surface in the direction parallel to the extending direction of the word line 10, the side surface being inclined so that a width of the upper word line 10b becomes narrower toward the top (e.g., a forward taper shape). Here, as can be seen from FIGS. 17 and 18, up to a height of a bit line buried oxide film 9 corresponds to the lower word line 10a.

Note that, in FIG. 15, a buried insulating film 11, an interlayer insulating film 12, the bit line buried oxide film 9, a trap film 6, and a bit interconnect 15 are not shown.

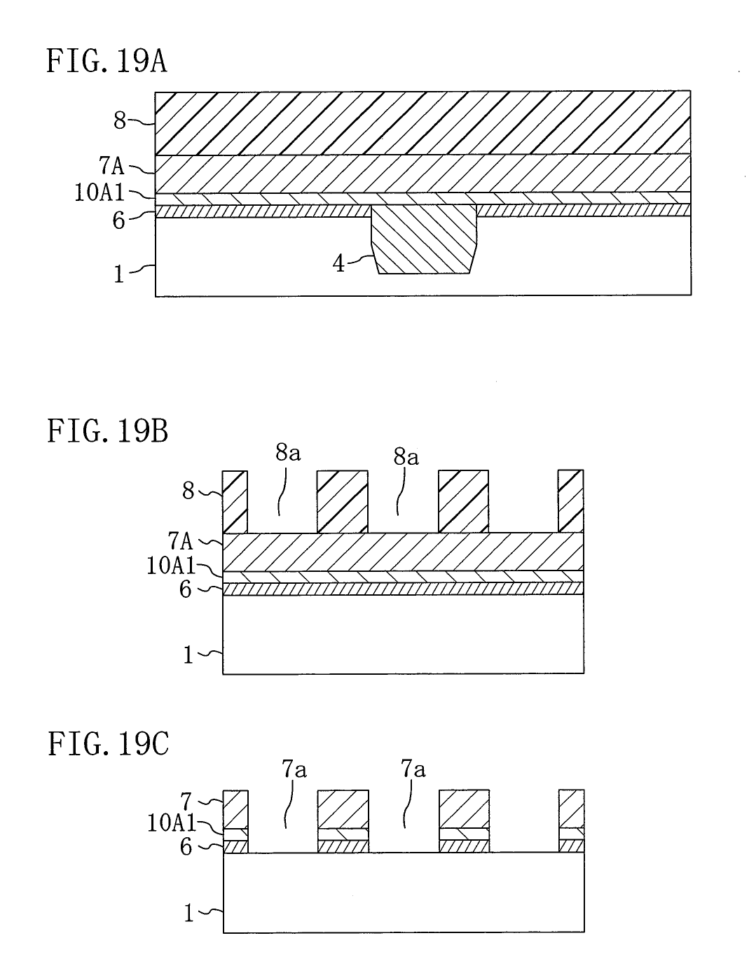

Hereinafter, a method for manufacturing the thus-configured semiconductor memory device will be described with reference to FIGS. 19A to 26B. Note that FIGS. 19A to 26B each correspond to a cross-section taken along any one of lines of FIG. 15. Specifically, FIGS. 19A, 22A, 23A, 24A, 25A and 26A correspond to a cross-section taken along line XVII-XVII of FIG. 15, FIGS. 19B to 21B correspond to a cross-section taken along line XVI-XVI of FIG. 15, and FIGS. 22B, 23B, 24B, 25B and 26B correspond to a cross-section taken along line XVIII-XVIII of FIG. 15.

Initially, as shown in FIG. 19A, an isolation region 4 (STI, etc.) made of silicon oxide is selectively formed on the semiconductor substrate 1 made of Si as in the first embodiment. Next, a trap film 6 that is an ONO film having a film thickness of 20 nm and has a site where electric charges are trapped is deposited on an entire surface of the semiconductor substrate 1 including the isolation region 4. Next, a first polycrystal silicon film 10A1 having a thickness of about 20 nm to 80 nm (e.g., 50 nm) is deposited by, for example, CVD, and a silicon oxide film (not shown) having a thin film thickness of about 10 nm is then deposited on the first polycrystal silicon film 10A1. Here, the first polycrystal silicon film 10A1 is doped with an n-type impurity during or after the deposition. Thereafter, a second mask formation film 7A made of silicon nitride having a film thickness of about 50 nm to 200 nm is deposited. Note that the silicon oxide film (not shown) is formed so as to protect the first polycrystal silicon film 10A1 when the second mask formation film 7A is subsequently selectively removed, and therefore, the silicon oxide film may not be used if the process of removing the second mask formation film 7A can be made more precise. Also, if the silicon oxide film (not shown) is removed, following the adjustment of the height of the bit line buried oxide film 9, the silicon oxide film does not have an influence on the subsequent word line formation step. Thereafter, a second resist film 8 is applied on the second mask formation film 7A.

Next, as shown in FIG. 19B, opening patterns 8a each having an opening for a source/drain formation region is formed in the second resist film 8 by lithography. Here, the opening has a width of 100 nm, which is a width of the source/drain region 5, i.e., a width of a diffusion bit line. On the other hand, the second resist film 8 has a line width of 150 nm, and this line width corresponds to a channel width of a memory cell transistor.

Next, as shown in FIG. 19C, the second mask formation film 7A is etched by dry etching or the like using the second resist film 8 to form, from the second mask formation film 7A, a second mask film 7 having opening portions 7a to which the opening patterns 8a of the second resist film 8 are transferred. Next, the silicon oxide film (not shown), the first polycrystal silicon film 10A1 and the trap film 6 that are exposed from the opening portion 7a of the second mask film 7 are removed. Note that since the trap film 6 has a film thickness of as small as 20 nm, the trap film 6 may not be removed and may be used as a protection film for the semiconductor substrate 1 during ion implantation.

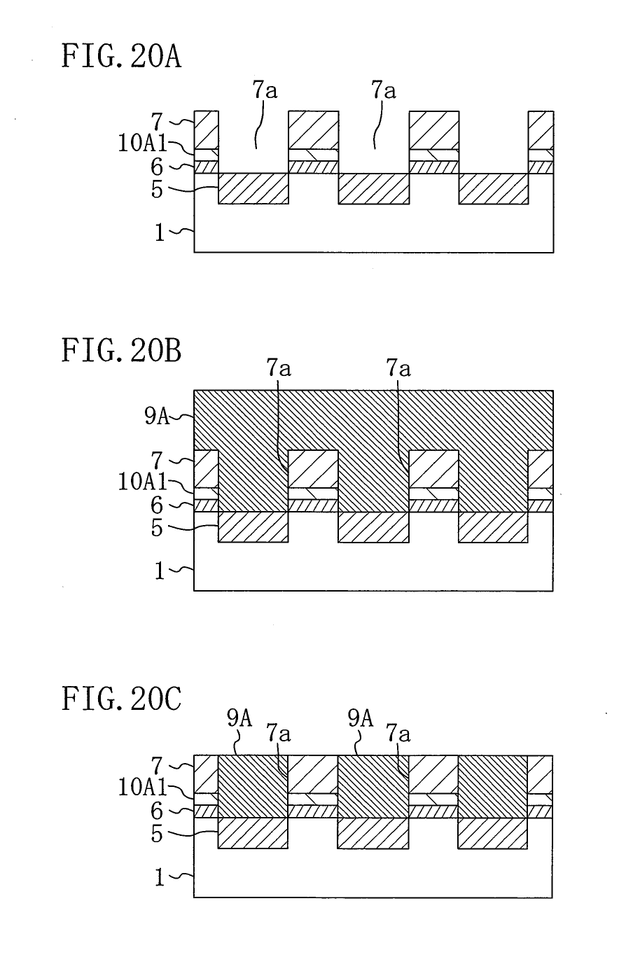

Next, as shown in FIG. 20A, ion implantation is performed once or twice or more using the second mask film 7 under conditions such that, for example, arsenic, which is an n-type impurity, is used, the acceleration energy is 5 keV to 200 keV, and the dose is 1×10¹⁴ cm⁻² to 1×10¹⁷ cm⁻², so that the source/drain regions 5 each made of an n-type impurity diffusion layer are formed.

Next, as shown in FIG. 20B, a silicon oxide film 9A is deposited by, for example, HDP-CVD, LP-CVD or the like, so that at least each opening portion 7a of the second mask film 7 is buried.

Next, as shown in FIG. 20C, the silicon oxide film 9A is removed by, for example, CMP, etch back or the like, leaving portions thereof buried in the opening portions 7a of the second mask film 7.

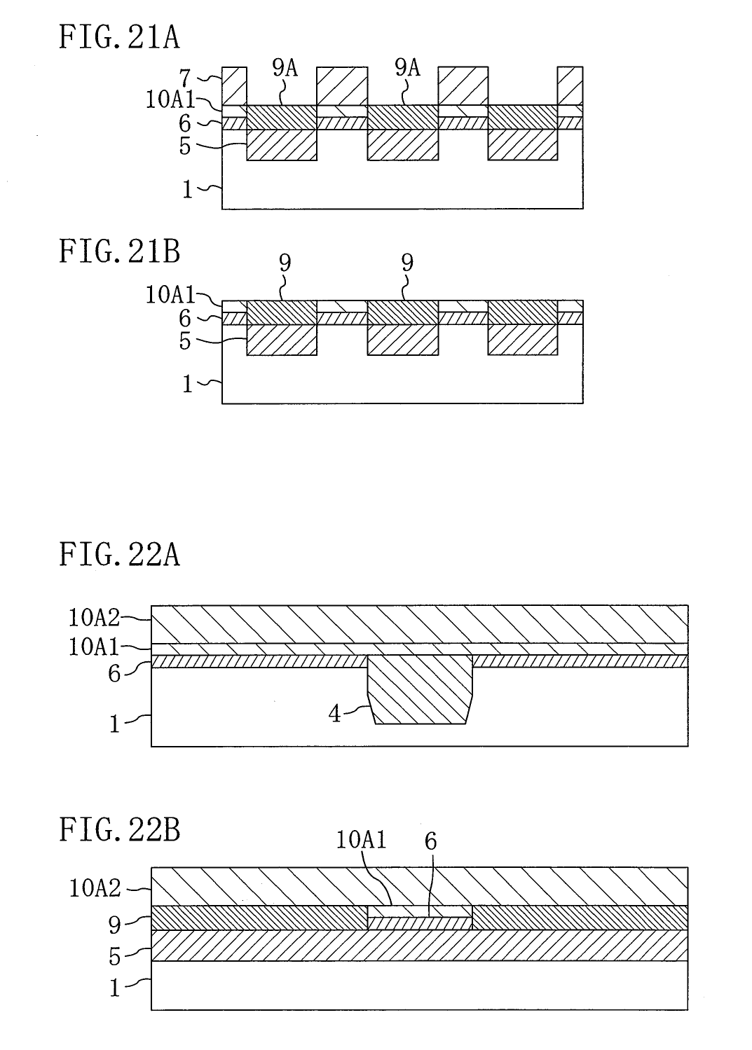

Next, as shown in FIG. 21A, a height of the buried silicon oxide film 9A is adjusted to substantially the same height of the first polycrystal silicon film 10A1 by wet etching or etch back.

Next, as shown in FIG. 21B, only the second mask film 7 is selectively removed by wet etching, etch back or the like. Next, the silicon oxide film (not shown) on the first polycrystal silicon film 10A1 is removed to form a bit line buried oxide film 9 from the silicon oxide film 9A. Thereby, a height of the bit line buried oxide film 9 is adjusted to substantially the same height as that of the first polycrystal silicon film 10A1. This height adjusting step is performed before the removal of the second mask film 7. In order to achieve the same height more precisely, the height adjusting step is preferably performed both before and after the removal of the second mask film 7.

Next, as shown in FIGS. 22A and 22B, a second polycrystal silicon film 10A2 that is doped with phosphorus (P), which is an n-type impurity, to about 1×10¹⁸ cm⁻³ to 1×10²² cm⁻³, is deposited on the first polycrystal silicon film 10A1 and the bit line buried oxide film 9 by, for example, LP-CVD. In this case, a very thin native oxide film having a film thickness of about 1 nm may be formed at an interface between the first polycrystal silicon film 10A1 and the second polycrystal silicon film 10A2. However, since the first polycrystal silicon film 10A1 and the second polycrystal silicon film 10A2 are electrically connected, such a native oxide film does not cause a problem when they are used as the word line (gate electrode).

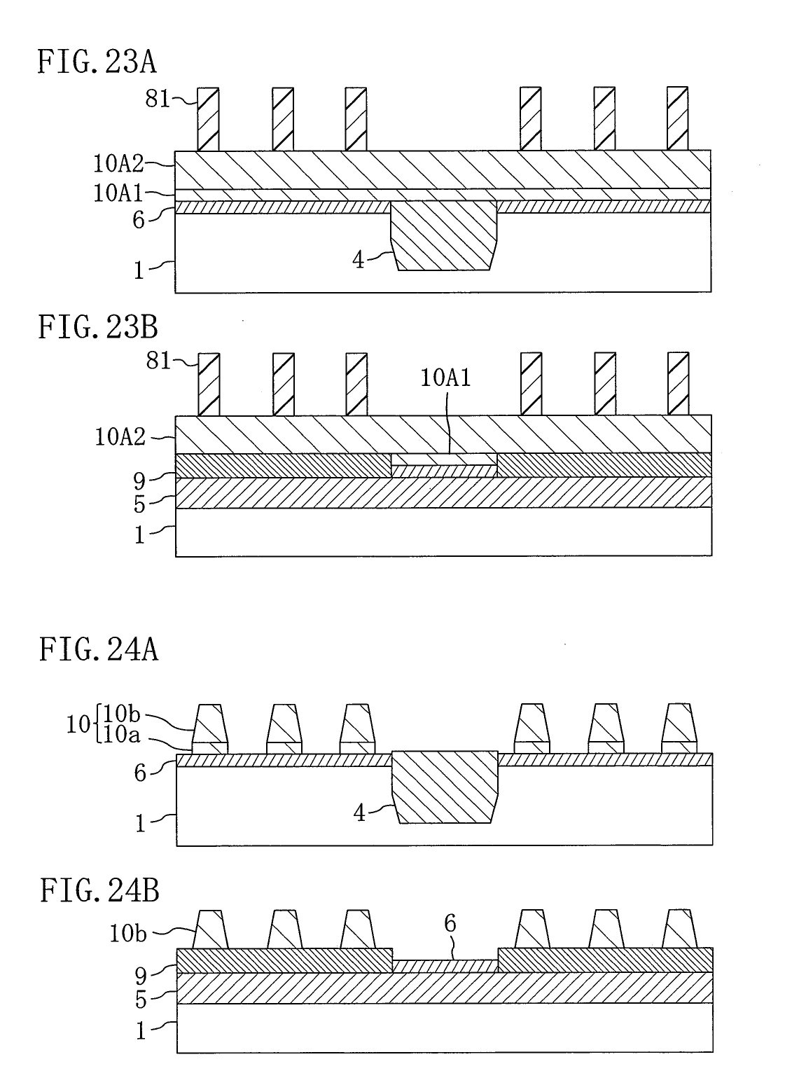

Next, as shown in FIGS. 23A and 23B, a third resist film 81 having a wiring pattern for forming a plurality of word lines is formed in a direction that intersects the source/drain formation region, on the second polycrystal silicon film 10A2 by lithography.

Next, as shown in FIGS. 24A and 24B, the word lines (gate electrodes) 10 including the lower word line 10a and the upper word line 10b thereon made of the first polycrystal silicon film 10A and the second polycrystal silicon film 10B, respectively, are formed by subjecting the second polycrystal silicon film 10B and the first polycrystal silicon film 10A to patterning by dry etching using the third resist film 81.

In this case, dry etching is performed with respect to the second polycrystal silicon film 10A2 so that the side surface in the direction parallel to the extending direction of each word line 10 has an angle of, for example, about 84°±4°, that is smaller than 90°, with respect to the semiconductor substrate 1 (first step). Next, when the etching of the second polycrystal silicon film 10A2 is ended, the interface oxide film (not shown) is removed by dry etching (second step). Thereafter, dry etching is performed with respect to the first polycrystal silicon film 10A1 so that the side surface in the direction parallel to the extending direction of each word line 10 has an angle of, for example, about 90°±1° with respect to the semiconductor substrate 1, thereby exposing the trap film 6 between each word line 10 (third step). Note that the switching of etching steps may include switching etching conditions while monitoring the film thickness during etching as in the first embodiment. Alternatively, a change in intensity of plasma light emission may be detected while the interface oxide film remains interposed, which is a known method.

The method for inclining the side surface of the second polycrystal silicon film 10A2 can be modified by adjusting a pressure or a gas composition during etching, the amount or depth of ions implanted into the second polycrystal silicon film 10A2, or an annealing time during which ions are diffused in the second polycrystal silicon film 10A2.

More specifically, the etching conditions for inclining the side surface of the second polycrystal silicon film 10A2 are specifically determined by changing the set values of etching parameters, depending on the required final angle of the side surface. Here, for example, conditions for setting the angle of the side surface of the upper word line 10b to be 84° are such that, in an inductively coupled high-density plasma etching apparatus, the etching gas species are chloride (Cl₂), hydrogen bromide (HBr), chloride tetrafluoride (CFO, and oxygen (O₂), and their flow rates are 50 ml/min, 175 ml/min, 35 ml/min, and 3.5 ml/min, respectively. In addition, the pressure is 5×133.3 mPa (=5 mTorr), the RF power of the upper electrode is set to be 600 W, the RF power of the lower electrode is set to be 125 V, and the temperature of the lower electrode is set to be 45° C.

Also, for example, in order to adjust the angle of the side surface of the upper word line 10b to 88°, the pressure is set to be 10×133.3 mPa (=10 mTorr) and the overall flow rate of the etching gas is set to be double.

The implantation amount and implantation energy of an impurity ion and annealing conditions are set so that the word line 10 finally has an appropriate resistance value. The angle of the side surface can also be adjusted by setting each parameter so that the profile of an ion implantation species becomes nonuniform when etching is performed. In this case, the final profile of the implantation species is caused to become uniform by annealing after implantation to the source/drain, and therefore, the profile of the implantation species does not need to be uniform during etching.

For example, conditions for causing the side surface of the word line 10 to have an angle of 86° are such that phosphorus ions are implanted at an acceleration energy of 15 keV and in a dose of 1×10¹⁴ cm², followed by RTA at 700° C. for 30 seconds. Also, for example, conditions for causing the side surface of the word line 10 to have an angle of 88° are such that RTA is performed at 850° C. for 30 seconds. Alternatively, the profile of the ion implantation species may be changed by setting implantation energy to be 35 keV.

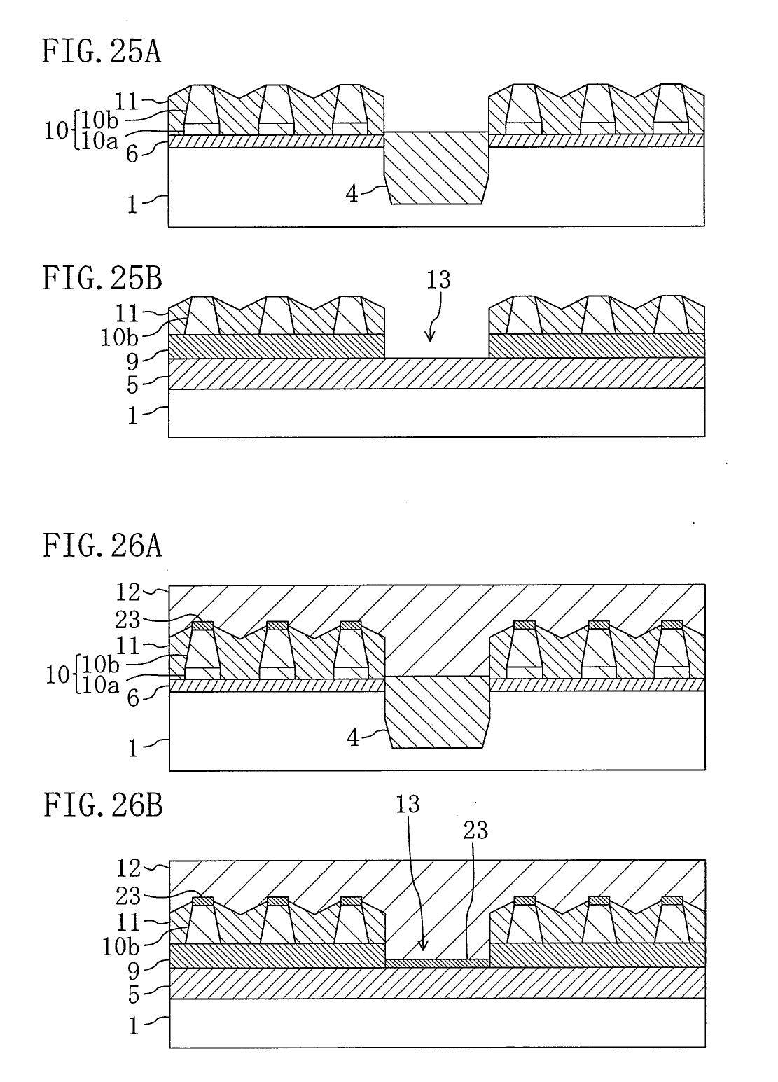

Next, as shown in FIGS. 25A and 25B, the third resist film 81 is removed before a buried insulating film 11 made of silicon oxide or silicon nitride is deposited by, for example, LP-CVD to fill an interstice between each word line 10. In this case, the upper portions of the side surfaces of adjacent upper word lines 10b become wider toward the top as described above. Therefore, substantially no void occurs in the buried insulating film 11. Next, the buried insulating film 11 on the upper surfaces of the word lines 10 and the bit line contact portion 13 is removed by etch back, leaving the buried insulating film 11 on the side surfaces of the word lines 10.

Next, as shown in FIGS. 26A and 26B, a metal film made of cobalt, nickel or the like is deposited on an entire surface of the semiconductor substrate 1 by, for example, vacuum vapor deposition or the like. Thereafter, a heat treatment is performed to form a metal silicide layer 23 in upper portions of each word line 10 and each bit line contact portion 13. Next, an interlayer insulating film 12 made of silicon oxide is deposited on an entire surface of the semiconductor substrate 1 by, for example, HDP-CVD, AP-CVD, PE-CVD or the like. Thereafter, an upper surface of the interlayer insulating film 12 is planarized by, for example, CMP, dry etch back or the like.

Subsequently, as shown in FIG. 18, a connection hole is formed so as to expose the bit line contact portion 13 of each source/drain region 5 formed in the upper portion of the semiconductor substrate 1. A metal monolayer film or a metal multilayer film made of, for example, tungsten, a tungsten compound, titanium, a titanium compound (titanium nitride (TiN), etc.) or the like is deposited on an entire surface of the interlayer insulating film 12, burying each connection hole, so that each contact 14 is formed. Next, a conductive film for formation of a bit interconnect is deposited on the interlayer insulating film 12, and the deposited conductive film is subjected to patterning so as to be electrically connected to each contact 14. Each bit interconnect 15 is thus formed from the conductive film.

According to the second embodiment, the side surface of each word line (gate electrode) 10 in a direction parallel to the extending direction of the word line 10 has the upper and lower portions having different angles. Specifically, the side surface of the lower word line 10a is perpendicular to the main surface of the semiconductor substrate 1, so that the side surface of the bit line buried oxide film 9 having substantially the same height as that of the lower word line 10a is also perpendicular to the main surface of the semiconductor substrate 1. Therefore, an etching residue does not occur on the side surface of the bit line buried oxide film 9. In contrast, the side surface of the upper word line 10b is inclined so that an interval between adjacent side surfaces becomes wider toward the top. Therefore, a void is unlikely to occur when the buried insulating film 11 is formed and buried between each word line 10.

Thus, also in the second embodiment, as is different from the conventional art, a void does not occur in the buried insulating film 11 that is formed between each word line (gate electrode) 10 to insulate and separate the word lines 10, and also, an etching residue does not occur on the side surface of the bit line buried oxide film 9. Therefore, microfabrication of the semiconductor memory device can be achieved with a satisfactory yield.

In addition, the lower word line 10a having a perpendicular side surface and the upper word line 10b having an inclined side surface that constitue each word line 10 are separately formed in the second embodiment. Therefore, the bit line buried oxide film 9 is formed while the first polycrystal silicon film 10A1 of the lower word line 10a has been formed. Therefore, it is easy to cause the first polycrystal silicon film 10A1 and the bit line buried oxide film 9 to have substantially the same height, thereby making it possible to control the yield more reliably.

Although it has been assumed in the second embodiment that the second mask film 7 for formation of the source/drain region 5 is made of silicon nitride, the second mask film 7 may be an insulating film made of a silicon compound, such as silicon oxide or the like, instead of silicon nitride. Also, when the source/drain region 5 is formed, a resist material may be used as a mask instead of a mask film made of a silicon compound.

It has also been assumed in the second embodiment that the trap film 6 having a site where electric charges are trapped is a multilayer film made of three films, i.e., silicon oxide, silicon nitride and silicon oxide films. Instead of this, a monolayer film made of silicon oxynitride, a monolayer film made of silicon nitride, a two-layer film including silicon oxide and silicon nitride films successively formed (i.e., the silicon oxide film closer to the semiconductor substrate 1), or a five-layer film including silicon oxide, silicon nitride, silicon oxide, silicon nitride and silicon oxide films successively deposited may be used.

Although it has also been assumed as an example in the second embodiment that the trap film 6 has a film thickness of 20 nm, the film thickness may be adjusted within 10 nm to 30 nm as appropriate so that transistor characteristics are optimized.

Although it has also been assumed as an example in the second embodiment that the first polycrystal silicon film 10A1 and the bit line buried oxide film 9 have a height of 50 nm, the height may be adjusted within 20 nm to 100 nm as appropriate so that a leakage current between the word line 10 and the source/drain region 5 is optimized.

Although it has also been assumed as an example in the second embodiment that the n-type impurity diffusion layer included in the source/drain region 5 has a width of 100 nm, the width may be adjusted within 50 nm to 300 nm as appropriate by optimizing transistor characteristics.

It has been assumed in the second embodiment that a resist material (third resist film 81) is used as a mask for dry etching with respect to the second polycrystal silicon film 10A2 and the first polycrystal silicon film 10A1 included in the word line 10. For a high scale of integration, a high etching selectivity is assumed to be required. In such a case, a mask film made of silicon oxide or silicon nitride may be used, or alternatively, a multilayer mask including these films and a resist material may be used.

Although it has also been assumed in the second embodiment that the step of performing dry etching with respect to the polycrystal silicon films 10A1 and 10A2 includes switching the step when etching with respect to the second polycrystal silicon film 10A2 reaches the height of the bit line buried oxide film 9, the present invention is not limited to this. Specifically, even if etching may be switched within about ±30 nm from the height of the bit line buried oxide film 9, it is possible to remove etching residue.

Although it has also been assumed in the second embodiment that the second polycrystal silicon film 10A2 included in the upper word line 10b is formed by depositing doped polysilicon, non-doped polycrystal silicon that is not doped with an impurity may be deposited before being doped by impurity implantation.

Also, the polycrystal silicon films 10A1 and 10A2 included in the word line 10 are only for illustrative purposes. Instead of polycrystal silicon, a monolayer film made of amorphous silicon, a high-melting point metal having a melting point of 600° C. or more (tantalum (Ta), titanium (Ti), etc.), a metal compound, or a metal silicide, or a multilayer film thereof may be used. Alternatively, the second polycrystal silicon film 10A2 of the upper word line 10b may be changed to silicide using a metal.

Although it has also been assumed as an example in the second embodiment that the buried insulating film 11 buried between each word line 10 is a silicon oxide film or a silicon nitride film formed by LP-CVD, the present invention is not limited to this. Specifically, any insulating film that has a satisfactory step coverage property and can be formed by a method without plasma may be used. Note that an insulating film that is formed by AP-CVD and hence needs to be subsequently baked at high temperature is difficult to handle and requires highly precise conditions for film formation and baking.

Although it has also been assumed in the second embodiment that a memory element whose source/drain region 5 is of n type is used, a p-type memory element may be used.

Also, in the second embodiment, a side surface and a bottom surface of the n-type impurity diffusion layer included in each source/drain region 5 may be covered by a p-type impurity diffusion layer having a lower impurity concentration than that of the n-type impurity diffusion layer. With this structure, the p-type impurity diffusion layer can suppress a short channel effect that is caused by diffusion of an impurity of the n-type impurity diffusion layer. Therefore, an interval between a pair of source/drain regions 5 can be reduced, i.e., the gate length can be reduced, so that the scale of integration of the semiconductor memory device can be further increased.

### Third Embodiment

Hereinafter, a third embodiment of the present invention will be described with reference to the drawings. Here, only a difference(s) from the semiconductor memory device of the first embodiment of the present invention will be described. Therefore, the same constituents as those of FIGS. 1 to 6 are indicated by the same reference numerals.

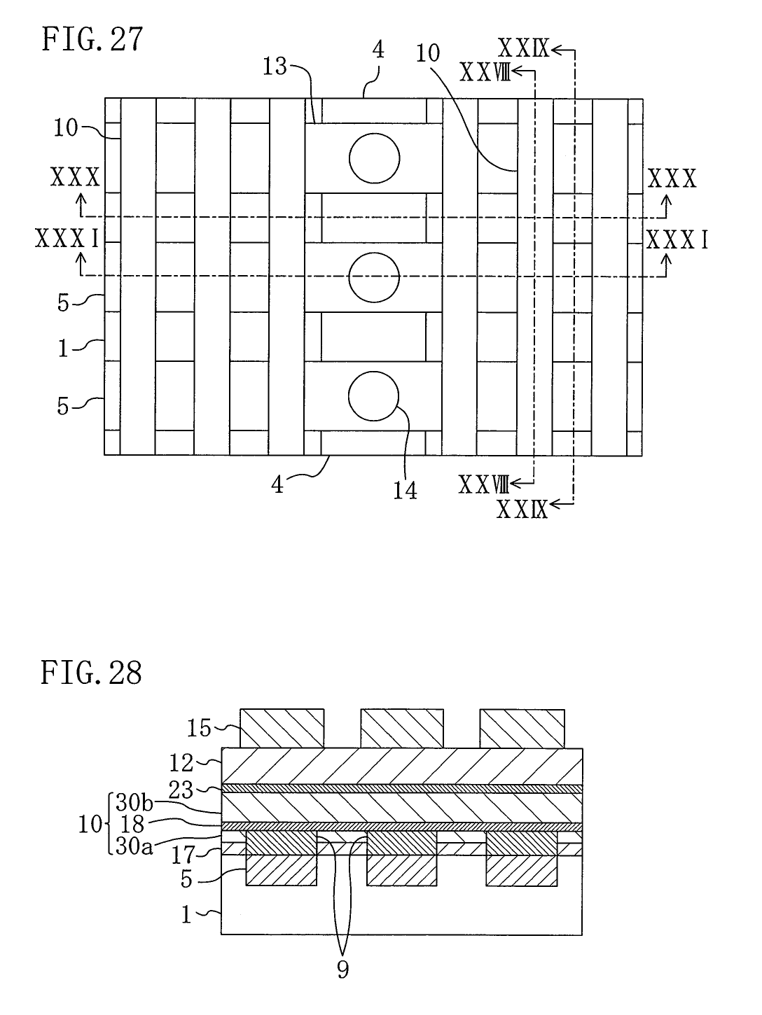

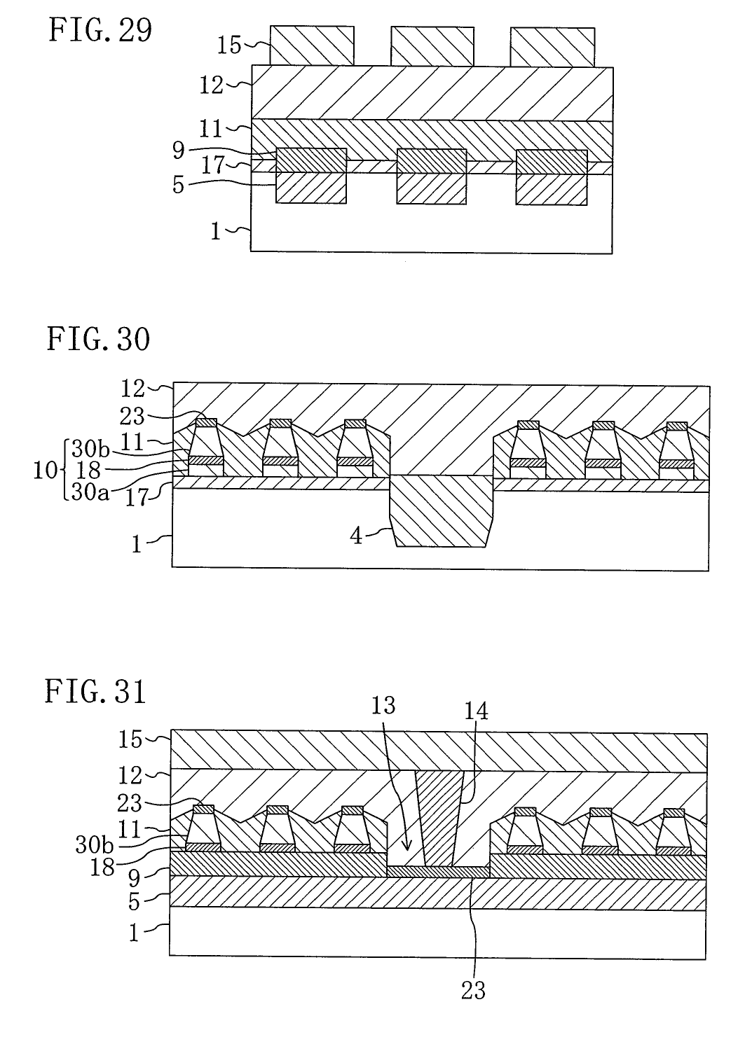

FIG. 27 shows a plan view of a memory cell region in the semiconductor memory device of the third embodiment of the present invention. FIGS. 28 to 31 show cross-sectional views taken along lines XXVIII-XXVIII, XXIX-XXIX, XXX-XXX and XXXI-XXXI of FIG. 27, respectively.

As shown in FIGS. 28, 29 and 30, a word line (gate electrode) 10 of the semiconductor memory device of the third embodiment includes a floating gate electrode 30a, an interelectrode insulating film 18 and a control gate electrode 30b that are formed via a tunnel film 17 made of silicon oxide on a main surface of a semiconductor substrate 1.

The floating gate electrode 30a and the control gate electrode 30b are each made of polycrystal silicon to which an n-type impurity (e.g., phosphorus (P), etc.) is introduced. The interelectrode insulating film 18 is an ONO film that is a stack of silicon oxide, silicon nitride and silicon oxide films.

The floating gate electrode 30a included in the word line 10 has a side surface in a direction parallel to an extending direction of the word line 10, the side surface being perpendicular to the main surface of the semiconductor substrate 1. The control gate electrode 30b has a side surface in the direction parallel to the extending direction of the word line 10, the side surface being inclined so that a width of the control gate electrode 30b becomes narrower toward the top (e.g., a forward taper shape). Here, as can be seen from FIGS. 30 and 31, up to a height of a bit line buried oxide film 9 corresponds to the floating gate electrode 30a.

Note that, in FIG. 27, a buried insulating film 11, an interlayer insulating film 12, the bit line buried oxide film 9, the tunnel film 17, and a bit interconnect 15 are not shown.

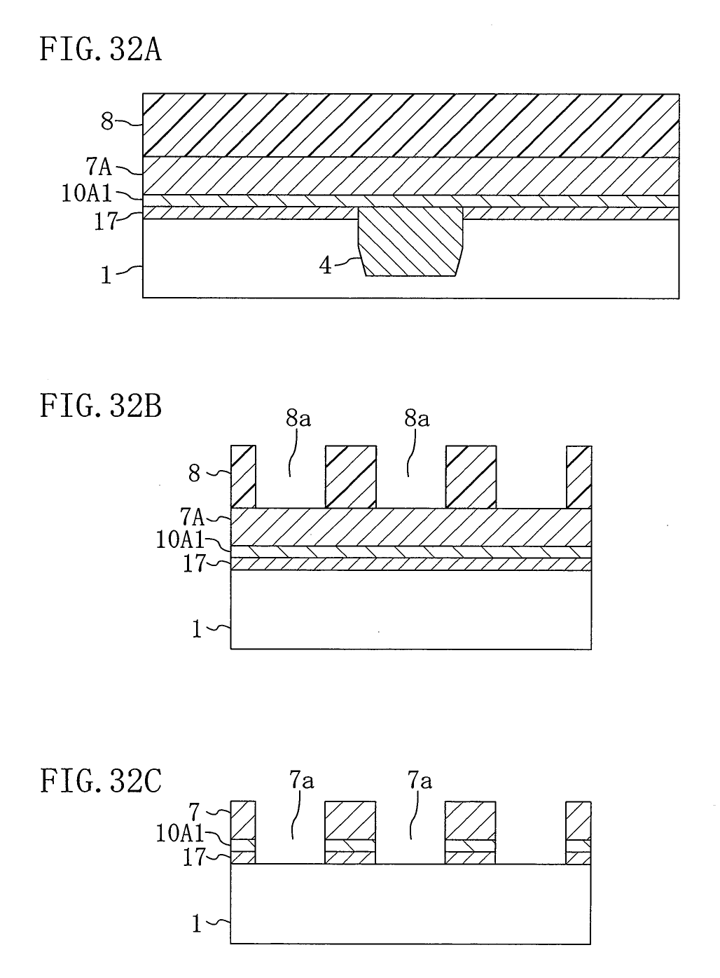

Hereinafter, a method for manufacturing the thus-configured semiconductor memory device will be described with reference to FIGS. 32A to 39B. Note that FIGS. 32A to 39B each correspond to a cross-section taken along any one of lines of FIG. 27. Specifically, FIGS. 32A, 35A, 36A, 37A, 38A and 39A correspond to a cross-section taken along line XXX-XXX of FIG. 27, FIGS. 32B to 34B correspond to a cross-section taken along line XXVIII-XXVIII of FIG. 27, and FIGS. 35B, 36B, 37B, 38B and 39B correspond to a cross-section taken along line XXXI-XXXI of FIG. 27.

Initially, as shown in FIG. 32A, an isolation region 4 (STI, etc.) made of silicon oxide is selectively formed on the semiconductor substrate 1 made of Si as in the first embodiment. Next, the tunnel film 17 made of silicon oxide having a film thickness of 10 nm is deposited on an entire surface of the semiconductor substrate 1 including the isolation region 4. Next, a first polycrystal silicon film 10A1 having a thickness of about 20 nm to 80 nm (e.g., 50 nm) and having an n-type conductivity is deposited by, for example, CVD, and a silicon oxide film (not shown) having a thin film thickness of about 10 nm is then deposited on the first polycrystal silicon film 10A1. Thereafter, a second mask formation film 7A made of silicon nitride having a film thickness of about 50 nm to 200 nm is deposited. Note that the silicon oxide film (not shown) is formed so as to protect the first polycrystal silicon film 10A1 when the second mask formation film 7A is subsequently selectively removed as in the second embodiment. Therefore, a second resist film 8 is applied on the second mask formation film 7A.

Next, as shown in FIG. 32B, opening patterns 8a each having an opening for a source/drain formation region is formed in the second resist film 8 by lithography. Here, the opening has a width of 100 nm, which is a width of the source/drain region 5, i.e., a width of a diffusion bit line. On the other hand, the second resist film 8 has a line width of 150 nm, and this line width corresponds to a channel width of a memory cell transistor.

Next, as shown in FIG. 32C, the second mask formation film 7A is etched by dry etching or the like using the second resist film 8 to form, from the second mask formation film 7A, a second mask film 7 having opening portions 7a to which the opening patterns 8a of the second resist film 8 are transferred. Next, the silicon oxide film (not shown), the first polycrystal silicon film 10A1 and the tunnel film 17 that are exposed from the opening portion 7a of the second mask film 7 are removed. Note that since the tunnel film 17 has a film thickness of as small as 10 nm, the tunnel film 17 may not be removed and may be used as a protection film during ion implantation.

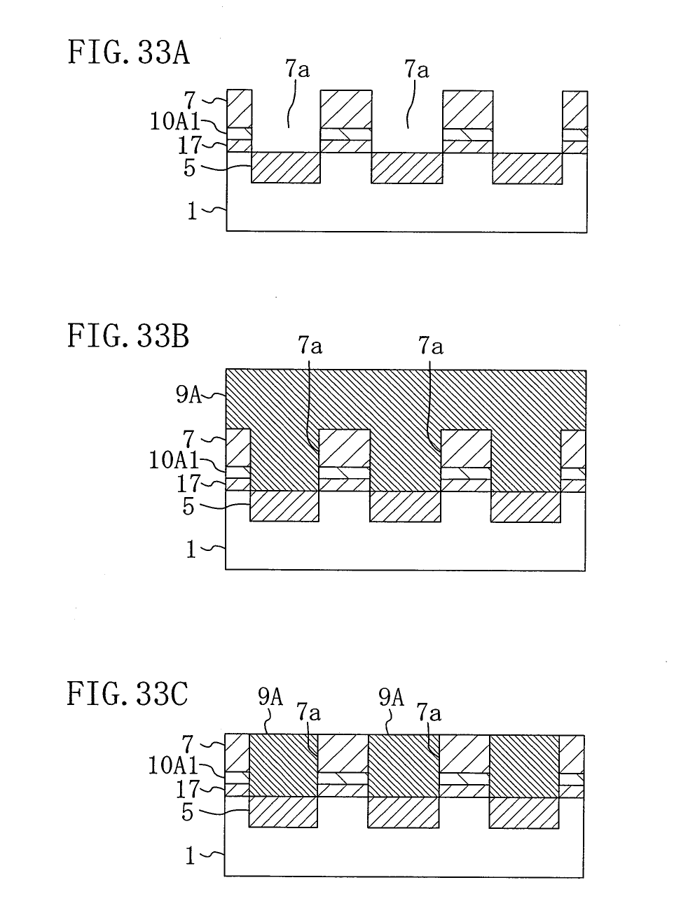

Next, as shown in FIG. 33A, ion implantation is performed once or twice or more using the second mask film 7 under conditions such that, for example, arsenic, which is an n-type impurity, is used, the acceleration energy is 5 keV to 200 keV, and the dose is 1×10¹⁴ cm⁻² to 1×10¹⁷ cm⁻², so that the source/drain regions 5 each made of an n-type impurity diffusion layer are formed.

Next, as shown in FIG. 33B, a silicon oxide film 9A is deposited by, for example, HDP-CVD, LP-CVD or the like, so that at least each opening portion 7a of the second mask film 7 is buried.

Next, as shown in FIG. 33C, the silicon oxide film 9A is removed by, for example, CMP, etch back or the like, leaving portions thereof buried in the opening portions 7a of the second mask film 7.

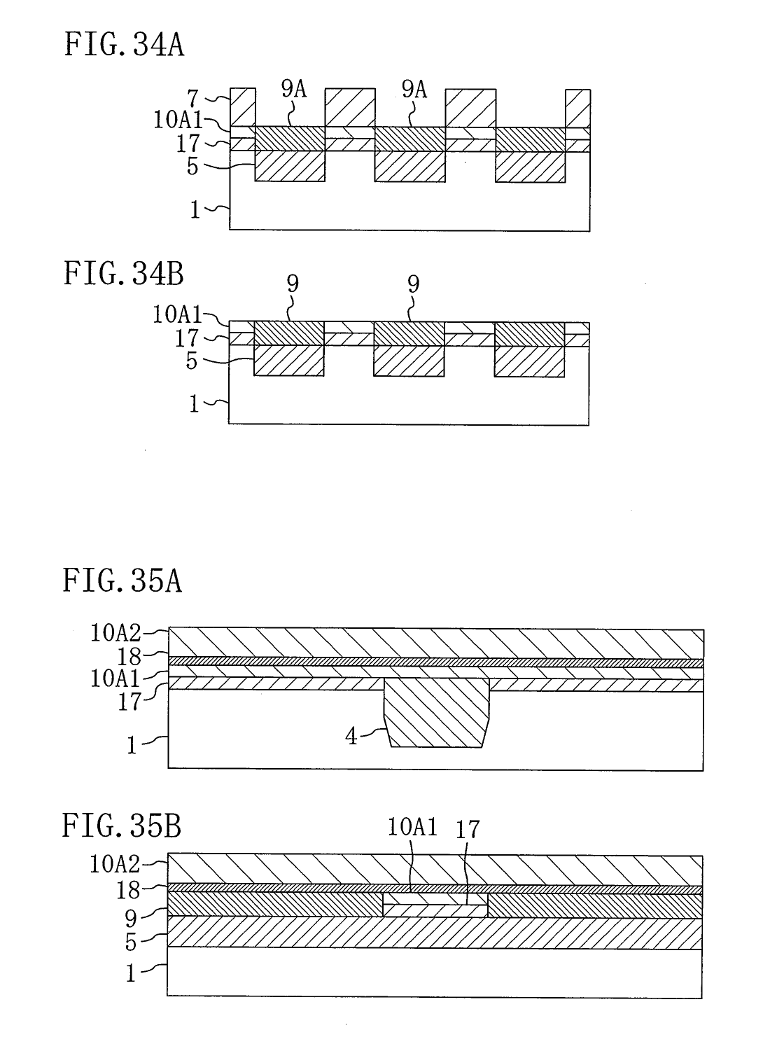

Next, as shown in FIG. 34A, a height of the buried silicon oxide film 9A is adjusted to substantially the same height of the first polycrystal silicon film 10A1 by wet etching or etch back.

Next, as shown in FIG. 34B, only the second mask film 7 is selectively removed by wet etching, etch back or the like. Next, the silicon oxide film (not shown) on the first polycrystal silicon film 10A1 is removed to form, from the silicon oxide film 9A, a bit line buried oxide film 9. Thereby, a height of the bit line buried oxide film 9 is adjusted to substantially the same height as that of the first polycrystal silicon film 10A1. This height adjusting step is performed before the removal of the second mask film 7. In order to achieve the same height more precisely, the height adjusting step is preferably performed both before and after the removal of the second mask film 7.

Next, as shown in FIGS. 35A and 35B, the interelectrode insulating film 18 made of a multilayer film of silicon oxide, silicon nitride and silicon oxide and having a film thickness of about 20 nm is formed on the first polycrystal silicon film 10A1 and the bit line buried oxide film 9 by, for example, LP-CVD. Next, a second polycrystal silicon film 10A2 that is doped with phosphorus, which is an n-type impurity, to about 1×10¹⁸ cm⁻³ to 1×10²² cm⁻³, is deposited on the interelectrode insulating film 18 by, for example, LP-CVD.

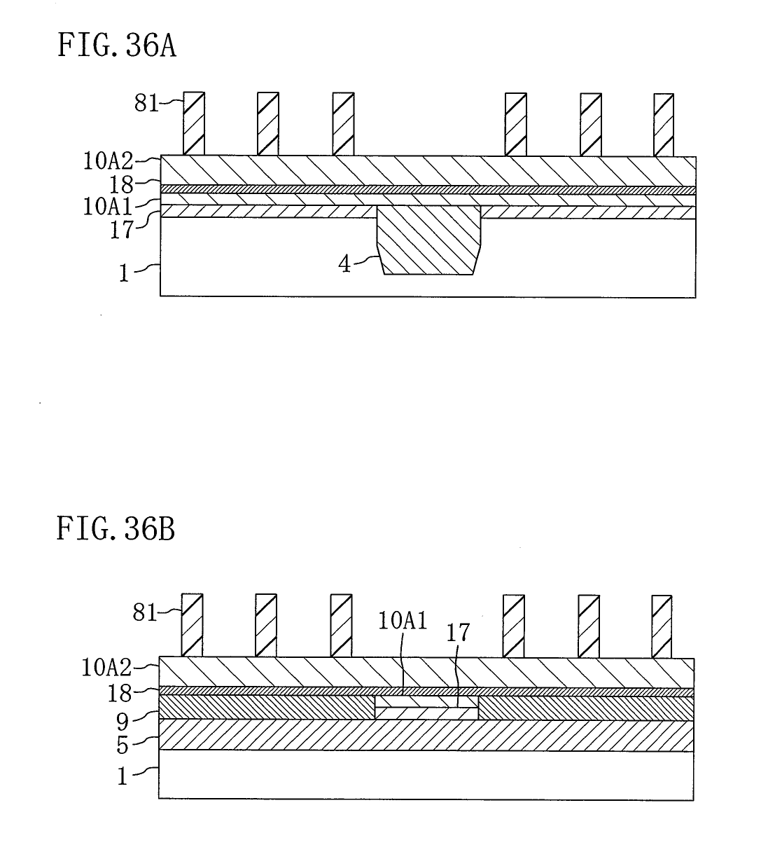

Next, as shown in FIGS. 36A and 36B, a third resist film 81 having a wiring pattern for forming a plurality of word lines is formed in a direction that intersects the source/drain formation region, on the second polycrystal silicon film 10A2 by lithography.

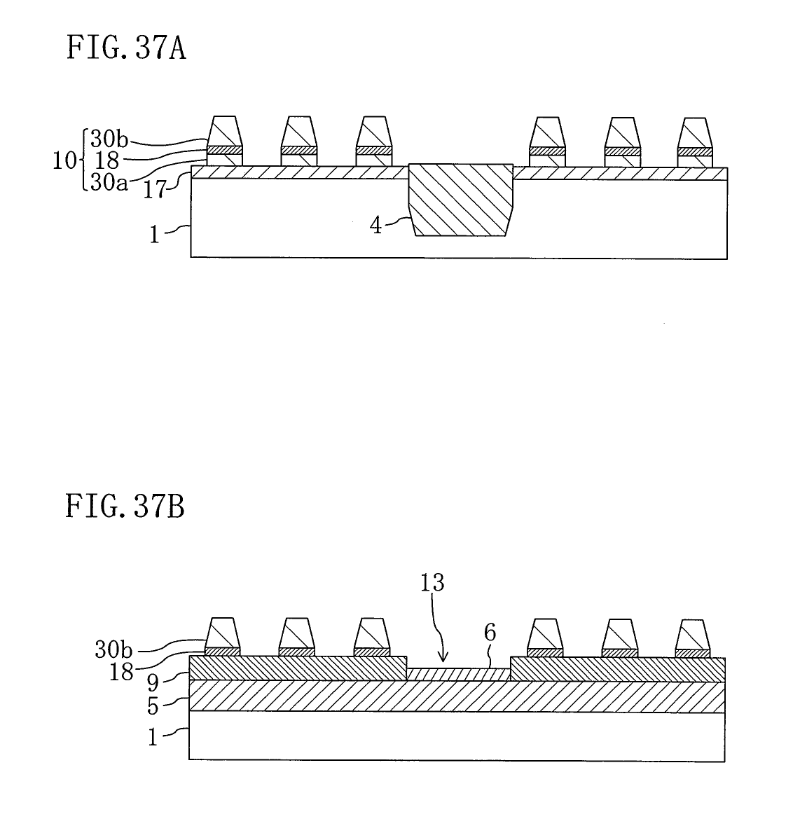

Next, as shown in FIGS. 37A and 37B, the word lines 10 including the floating gate electrode 30a, the interelectrode insulating film 18 and the control gate electrode 30b made of the first polycrystal silicon film 10A, the interelectrode insulating film 18 and the second polycrystal silicon film 10A2, respectively, are formed by subjecting the second polycrystal silicon film 10A2, the interelectrode insulating film 18 and the first polycrystal silicon film 10A1 to patterning by dry etching using the third resist film 81.

In this case, dry etching is performed with respect to the second polycrystal silicon film 10A2 so that the side surface in the direction parallel to the extending direction of each word line 10 has an angle of, for example, about 84°±4°, that is smaller than 90°, with respect to the semiconductor substrate 1 (first step). Next, when the etching of the second polycrystal silicon film 10A2 is ended, so that the interelectrode insulating film 18 is exposed, the interelectrode insulating film 18 is removed by dry etching (second step). Thereafter, dry etching is performed with respect to the first polycrystal silicon film 10A1 so that the side surface in the direction parallel to the extending direction of each word line 10 has an angle of, for example, about 90°±1° with respect to the semiconductor substrate 1, thereby exposing the tunnel film 17 between each word line 10 (third step). Note that the switching of etching steps may include switching etching conditions while monitoring the film thickness during etching as in the first embodiment. Alternatively, a change in intensity of plasma light emission may be detected while a known interface oxide film remains interposed.

The method for inclining the side surface of the second polycrystal silicon film 10A2 can be modified by adjusting a pressure or a gas composition during etching, the amount or depth of ions implanted into the second polycrystal silicon film 10A2, or an annealing time during which ions are diffused in the second polycrystal silicon film 10A2.

More specifically, the etching conditions for inclining the side surface of the second polycrystal silicon film 10A2 are specifically determined by changing the set values of etching parameters, depending on the required final angle of the side surface. Here, for example, conditions for setting the angle of the side surface of the control gate electrode 30b to be 84° are such that, in an inductively coupled high-density plasma etching apparatus, the etching gas species are chloride (Cl₂), hydrogen bromide (HBr), chloride tetrafluoride (CF₄), and oxygen (O₂), and their flow rates are 50 ml/min, 175 ml/min, 35 ml/min, and 3.5 ml/min, respectively. In addition, the pressure is 5×133.3 mPa (=5 mTorr), the RF power of the upper electrode is set to be 600 W, the RF power of the lower electrode is set to be 125 V, and the temperature of the lower electrode is set to be 45° C.

Also, for example, in order to adjust the angle of the side surface of the control gate electrode 30b to 88°, the pressure is set to be 10×133.3 mPa (=10 mTorr) and the overall flow rate of the etching gas is set to be double.

The implantation amount and implantation energy of an impurity ion and annealing conditions are set so that the word line 10 finally has an appropriate resistance value. The angle of the side surface can also be adjusted by setting each parameter so that the profile of an ion implantation species becomes nonuniform when etching is performed. In this case, the final profile of the implantation species is caused to become uniform by annealing after implantation to the source/drain, and therefore, the profile of the implantation species does not need to be uniform during etching.

For example, conditions for causing the side surface of the word line 10 to have an angle of 86° are such that phosphorus ions are implanted at an acceleration energy of 15 keV and in a dose of 1×10¹⁴ cm⁻², followed by RTA at 700° C. for 30 seconds. Also, for example, conditions for causing the side surface of the word line 10 to have an angle of 88° are such that RTA is performed at 850° C. for 30 seconds. Alternatively, the profile of the ion implantation species may be changed by setting implantation energy to be 35 keV.

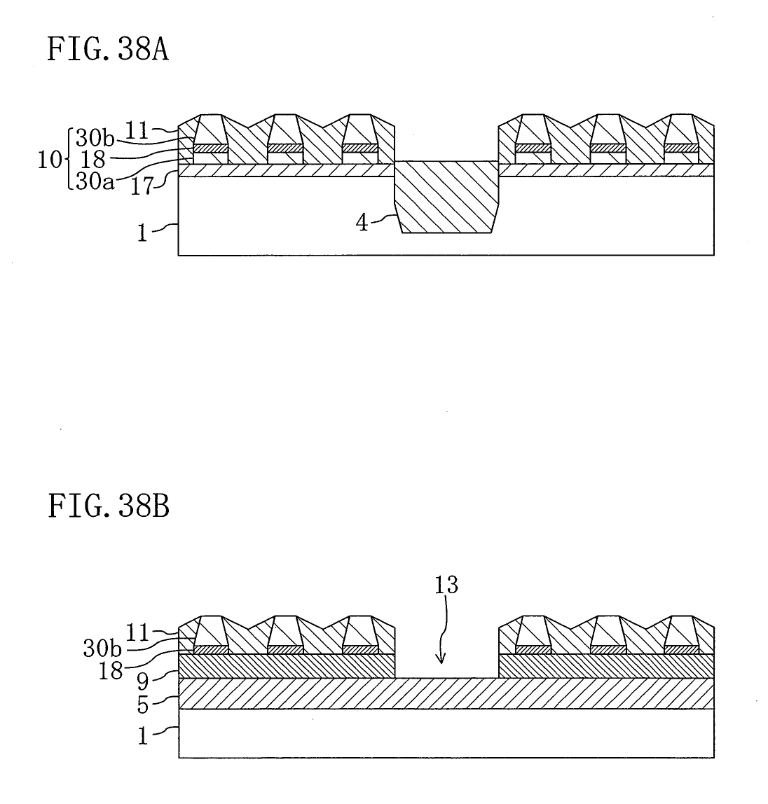

Next, as shown in FIGS. 38A and 38B, the third resist film 81 is removed before a buried insulating film 11 made of silicon oxide or silicon nitride is deposited by, for example, LP-CVD to fill an interstice between each word line 10. In this case, the upper portions of the side surfaces of adjacent control gate electrodes 30b become wider toward the top as described above. Therefore, substantially no void occurs in the buried insulating film 11. Next, the buried insulating film 11 on the upper surfaces of the word lines 10 and the bit line contact portion 13 is removed by etch back, leaving the buried insulating film 11 on the side surfaces of the word lines 10.

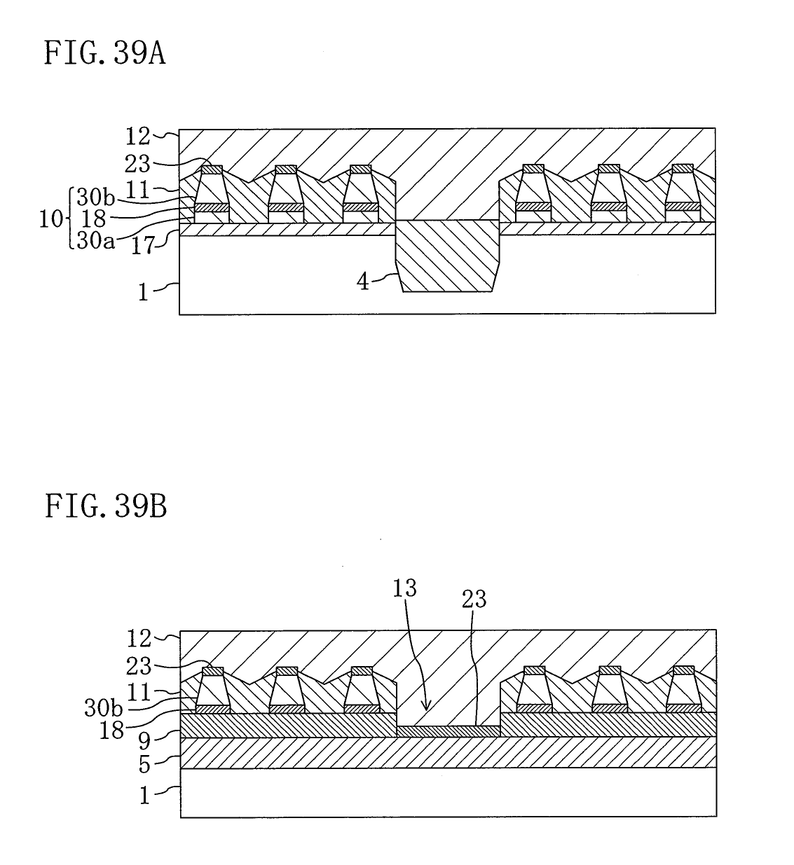

Next, as shown in FIGS. 39A and 39B, a metal film made of cobalt, nickel or the like is deposited on an entire surface of the semiconductor substrate 1 by, for example, vacuum vapor deposition or the like. Thereafter, a heat treatment is performed to form a metal silicide layer 23 in upper portions of each word line 10 (control gate electrode 30b) and each bit line contact portion 13. Next, an interlayer insulating film 12 made of silicon oxide is deposited on an entire surface of the semiconductor substrate 1 by, for example, HDP-CVD, AP-CVD, PE-CVD or the like. Thereafter, an upper surface of the interlayer insulating film 12 is planarized by, for example, CMP, dry etch back or the like.

Subsequently, as shown in FIG. 31, a connection hole is formed so as to expose the bit line contact portion 13 of each source/drain region 5 formed in the upper portion of the semiconductor substrate 1. A metal monolayer film or a metal multilayer film made of, for example, tungsten, a tungsten compound, titanium, a titanium compound (titanium nitride (TiN), etc.) or the like is deposited on an entire surface of the interlayer insulating film 12, burying each connection hole, so that each contact 14 is formed. Next, a conductive film for formation of a bit interconnect is deposited on the interlayer insulating film 12, and the deposited conductive film is subjected to patterning so as to be electrically connected to each contact 14. Each bit interconnect 15 is thus formed from the conductive film.

According to the third embodiment, the floating gate electrode 30a and the control gate electrode 30b formed thereon via the interelectrode insulating film 18 that are included in each word line (gate electrode) 10 have their side surfaces in the direction parallel to the extending direction of the word line 10, the side surfaces having different angles. Specifically, the side surface of the floating gate electrode 30a is perpendicular to the main surface of the semiconductor substrate 1, so that the side surface of the bit line buried oxide film 9 having substantially the same height as that of the floating gate electrode 30a is also perpendicular to the main surface of the semiconductor substrate 1. Therefore, an etching residue does not occur on the side surface of the bit line buried oxide film 9. In contrast, the side surface of the control gate electrode 30b is inclined so that an interval between adjacent side surfaces becomes wider toward the top. Therefore, a void is unlikely to occur when the buried insulating film 11 is formed and buried between each word line 10.

Thus, also in the third embodiment, as is different from the conventional art, a void does not occur in the buried insulating film 11 that is formed between each word line (gate electrode) 10 to insulate and separate the word lines 10, and also, an etching residue does not occur on the side surface of the bit line buried oxide film 9. Therefore, microfabrication of the semiconductor memory device can be achieved with a satisfactory yield.

Also, in the third embodiment, the floating gate electrode 30a and the control gate electrode 30b can be formed in a self-aligning manner and are therefore more easily formed than when they are separately formed. Therefore, a higher scale of integration can be easily achieved by this embodiment.

In addition, the bit line buried oxide film 9 is formed while the first polycrystal silicon film 10A1 of the floating gate electrode 30a has been formed. Therefore, it is easy to cause the first polycrystal silicon film 10A1 and the bit line buried oxide film 9 to have substantially the same height, thereby making it possible to control the yield more reliably.

Although it has been assumed in the third embodiment that the second mask film 7 for formation of the source/drain region 5 is made of silicon nitride, the second mask film 7 may be an insulating film made of a silicon compound, such as silicon oxide or the like, instead of silicon nitride. Also, when the source/drain region 5 is formed, a resist material may be used as a mask instead of a mask film made of a silicon compound.

It has also been assumed in the third embodiment that the tunnel film 17 has a film thickness of 10 nm, the film thickness may be adjusted within 5 nm to 30 nm as appropriate so that transistor characteristics are optimized.

Although it has also been assumed as an example in the third embodiment that the first polycrystal silicon film 10A1 and the bit line buried oxide film 9 have a height of 50 nm, the height may be adjusted within 20 nm to 100 nm as appropriate so that a leakage current between the word line 10 and the source/drain region 5 is optimized.

Although it has also been assumed as an example in the third embodiment that the n-type impurity diffusion layer included in the source/drain region 5 has a width of 100 nm, the width may be adjusted within 50 nm to 300 nm as appropriate by optimizing transistor characteristics.

It has been assumed in the third embodiment that a resist material (third resist film 81) is used as a mask for dry etching with respect to the second polycrystal silicon film 10A2 and the first polycrystal silicon film 10A1 included in the word line 10. For a high scale of integration, a high etching selectivity is assumed to be required. In such a case, a mask film made of silicon oxide or silicon nitride may be used, or alternatively, a multilayer mask including these films and a resist material may be used.

Although it has also been assumed in the third embodiment that the step of performing dry etching with respect to the polycrystal silicon films 10A1 and 10A2 includes switching the step at the interelectrode insulating film 18, the present invention is not limited to this. Specifically, even if etching may be switched within about ±30 nm from the height of the bit line buried oxide film 9, it is possible to remove etching residue.

Although it has also been assumed in the third embodiment that the first polycrystal silicon film 10A1 and the second polycrystal silicon film 10A2 are formed by depositing doped polysilicon, non-doped polycrystal silicon that is not doped with an impurity may be deposited before being doped by impurity implantation.

Also, the polycrystal silicon films 10A1 and 10A2 are only for illustrative purposes. Instead of polycrystal silicon, a monolayer film made of amorphous silicon, a high-melting point metal having a melting point of 600° C. or more (tantalum (Ta), titanium (Ti), etc.), a metal compound, or a metal silicide, or a multilayer film thereof may be used. Alternatively, the second polycrystal silicon film 10A2 may be changed to silicide using a metal.

Although it has also been assumed as an example in the third embodiment that the buried insulating film 11 buried between each word line 10 is a silicon oxide film or a silicon nitride film formed by LP-CVD, the present invention is not limited to this. Specifically, any insulating film that has a satisfactory step coverage property may be used. Note that if a memory element includes the floating gate electrode 30a, then the scale of integration is high, a capacitance between each floating gate electrode 30a increases, leading to a significant deterioration in characteristics. In such a case, therefore, the buried insulating film 11 needs to be made of a low-k dielectric material.

Although it has also been assumed in the third embodiment that a memory element whose source/drain region 5 is of n type is used, a p-type memory element may be used.

Also, in the third embodiment, a side surface and a bottom surface of the n-type impurity diffusion layer included in each source/drain region 5 may be covered by a p-type impurity diffusion layer having a lower impurity concentration than that of the n-type impurity diffusion layer. With this structure, the p-type impurity diffusion layer can suppress a short channel effect that is caused by diffusion of an impurity of the n-type impurity diffusion layer. Therefore, an interval between a pair of source/drain regions 5 can be reduced, i.e., the gate length can be reduced, so that the scale of integration of the semiconductor memory device can be further increased.

### Fourth Embodiment

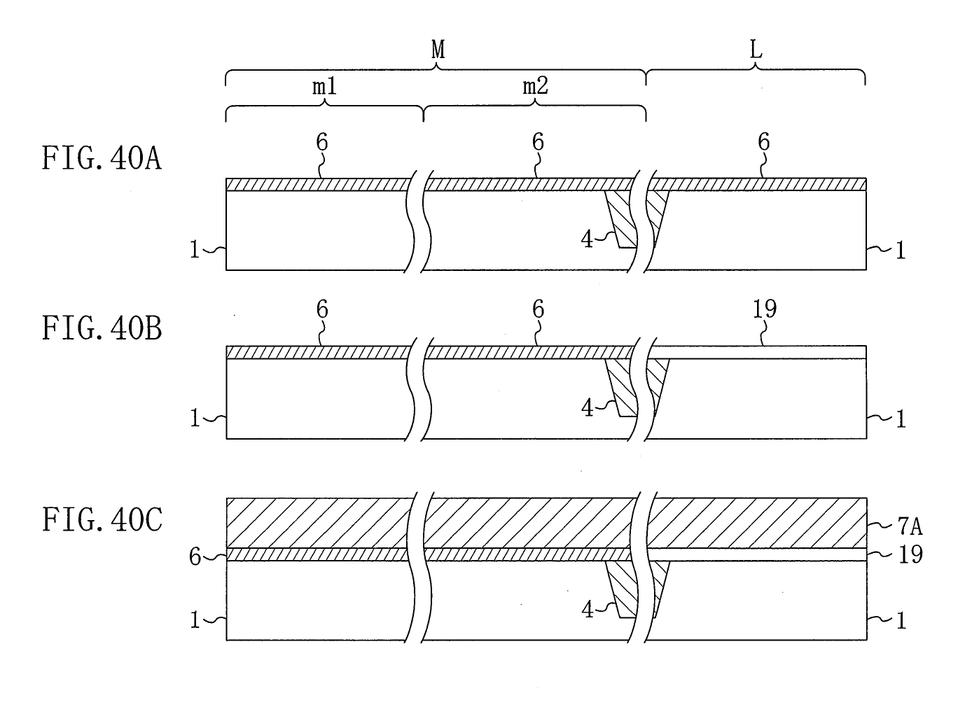

Hereinafter, a semiconductor memory device according to a fourth embodiment of the present invention and its manufacturing method will be described with reference to FIGS. 40A to 43C.

The semiconductor memory device of the fourth embodiment includes a memory element portion having a memory cell according to the first embodiment, and a logic circuit portion including a peripheral circuit or the like. Here, a method for manufacturing the semiconductor memory device of this embodiment will be described. Therefore, the memory element portion of the fourth embodiment can be manufactured by a method similar to that of the first embodiment.

Initially, as shown in FIG. 40A, a main surface of a semiconductor substrate 1 made of silicon is divided into a memory element portion M and a logic circuit portion L by an isolation region 4 (e.g., STI, etc.). Note that the memory element portion M includes a region m1 corresponding to a cross-section taken along line of FIG. 1 and a region m2 corresponding to a cross-section taken along line IV-IV of FIG. 1. The logic circuit portion L typically includes an n-channel transistor and a p-channel transistor. Since both transistors are different only in that they include impurity ions of different conductive types. Therefore, as an example, only the n-channel transistor is here shown.

Next, a trap film 6 that is an ONO film having a film thickness of 20 nm is deposited on an entire surface of the main surface of the semiconductor substrate 1 including the isolation region 4. In this case, the trap film 6 may be formed thinner by a film thickness of a gate insulating film that will be formed in the logic circuit portion L in a subsequent step.

Next, as shown in FIG. 40B, a portion of the trap film 6 that is deposited in the logic circuit portion L is removed, and thereafter, a gate insulating film 19 that is made of silicon oxide (e.g., a thermal oxide film) and has a film thickness of 3 nm is selectively formed on an entire surface of the logic circuit portion L of the main surface of the semiconductor substrate 1.

Next, as shown in FIG. 40C, a second mask formation film 7A made of silicon nitride having a film thickness of about 50 nm to 200 nm is formed on the trap film 6 and the gate insulating film 19.

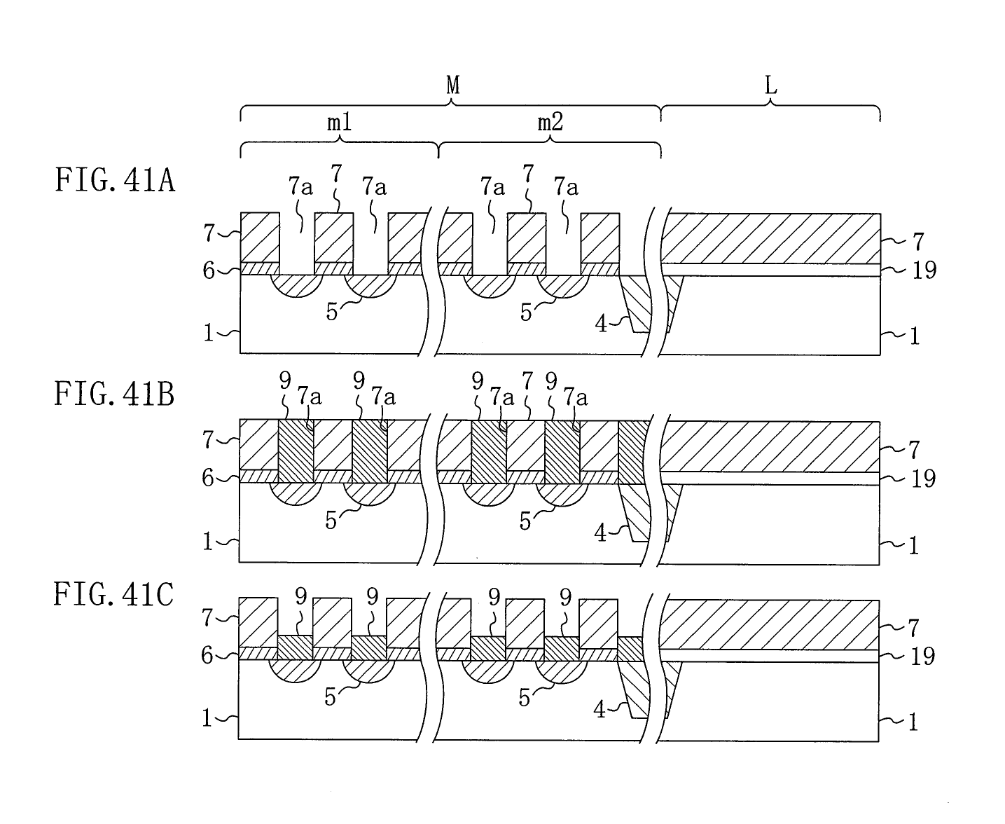

Next, as shown in FIG. 41A, stripe-shaped opening portions 7a having openings for source/drain formation regions of the memory element portion M are formed in the second mask formation film 7A by lithography and dry etching, and a second mask film 7 is obtained from the second mask formation film 7A. Further, the trap film 6 that is exposed from each opening portion 7a of the second mask film 7 is removed by etching. Here, the opening portion 7a of the second mask film 7 has an opening width of 100 nm, which is a width of the source/drain region. On the other hand, each line width of the second mask film 7 is 150 nm, which is a channel width of a memory cell transistor. Note that, as described in the first embodiment, the trap film 6 that is exposed from each opening portion 7a of the second mask film 7 may not be necessarily removed. Next, ion implantation is performed with respect to the memory element portion M of the semiconductor substrate 1 once or twice or more using the second mask film 7 under conditions such that, for example, arsenic, which is an n-type impurity, is used, the acceleration energy is 5 keV to 200 keV, and the dose is 1×10¹⁴ cm⁻² to 1×10¹⁷ cm⁻², so that source/drain regions 5 each made of an n-type impurity diffusion layer are formed.

Next, as shown in FIG. 41B, a bit line buried oxide film 9 made of silicon oxide is deposited, burying each opening portion 7a of the second mask film 7, and thereafter, an upper surface of the bit line buried oxide film 9 is planarized.

Next, as shown in FIG. 41C, a height of the bit line buried oxide film 9 is adjusted to 50 nm by wet etching or dry etch back.

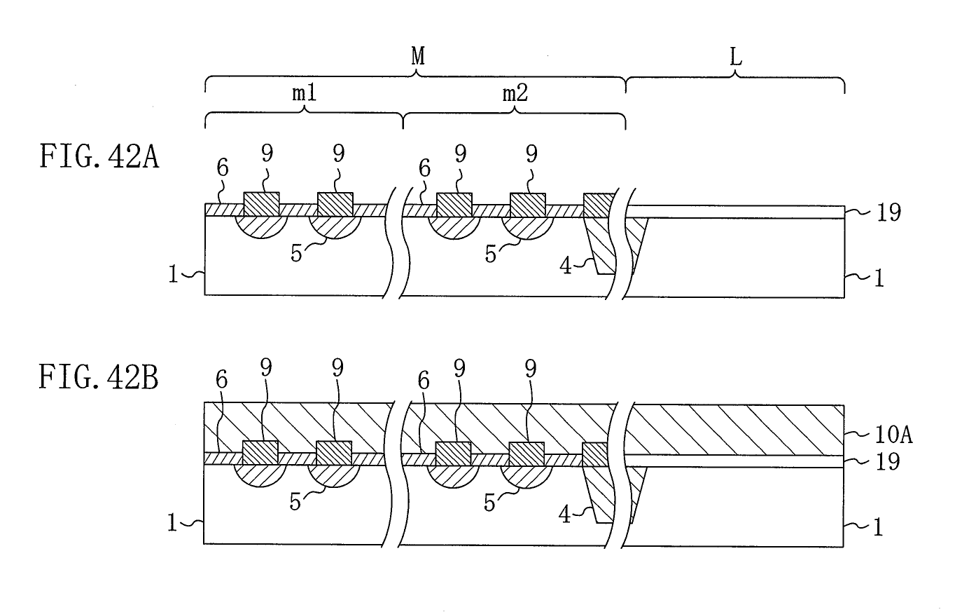

Next, as shown in FIG. 42A, only the second mask film 7 is selectively removed by wet etching or etch back. Thereby, in the memory element portion M, the trap film 6 is exposed while the bit line buried oxide film 9 is formed. At the same time, the gate insulating film 19 is exposed in the logic circuit portion L.

Next, as shown in FIG. 42B, a polycrystal silicon film 10A that is doped with phosphorus (n type) to about 1×10¹⁸ cm⁻³ to 1×10²² cm⁻³ is deposited on the trap film 6 and the bit line buried oxide film 9 in the memory element portion M, and on the gate insulating film 19 in the logic circuit portion L.

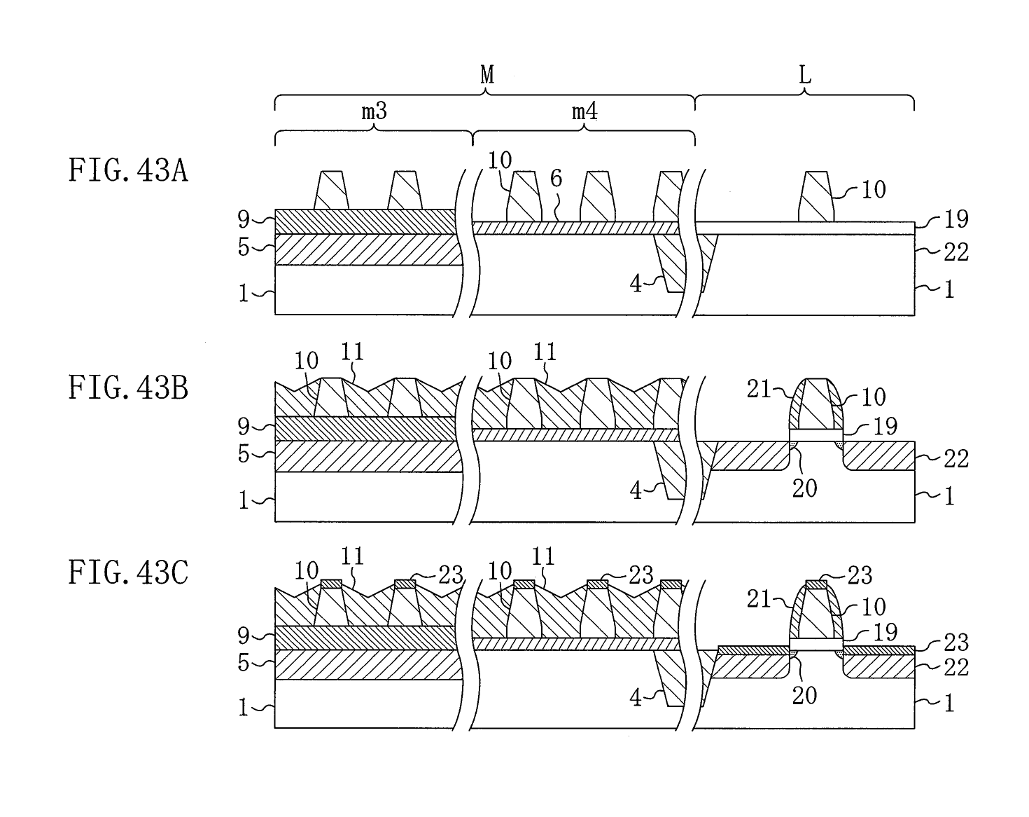

Next, as shown in FIG. 43A, the deposited polycrystal silicon film 10A is selectively subjected to the following two-step dry etching, thereby forming, from the polycrystal silicon film 10A, word lines 10 that interest the source/drain regions 5 in the memory element portion M. Also, a word line (gate electrode) 10 of a transistor is formed in the logic circuit portion L. Here, a region m3 corresponds to a cross-section taken along line VI-VI of FIG. 1 and the region m4 corresponds to a cross-section taken along line V-V of FIG. 1.

Specifically, etching is performed with respect to the polycrystal silicon film 10A so that a width of an upper portion of both side surfaces in a direction parallel to an extending direction of the word line 10 becomes narrower toward the top (forward taper shape) (first step). Next, when a height of a lower end portion of etching becomes substantially equal to a height of the bit line buried oxide film 9, etching is performed with respect to a lower portion of the polycrystal silicon film 10A so that a side surface thereof is substantially perpendicular to the main surface of the semiconductor substrate 1 (second step). As an example, the upper portion of the side surface of the word line 10 is caused to have an angle of about 84°±4° in the first step. Etching is performed so that the lower portion of the side surface of the word line 10 has an angle of about 90°±1° in the second step. Thereby, the trap film 6 is exposed between each word line 10 in the region m4 of the memory element portion M, and the gate insulating film 19 is exposed in the logic circuit portion L. Note that specific process conditions under which the upper portion of both side surfaces of the word line 10 is caused to have a forward taper shape and a method for switching etching steps while monitoring a film thickness during etching have been described above.

Next, as shown in FIG. 43B, an n-type impurity ion is implanted into the logic circuit portion L of the semiconductor substrate 1 using the word line (gate electrode) 10 as a mask, thereby forming a low-concentration impurity diffusion layer 20 in regions on both sides of the gate electrode 10 of the semiconductor substrate 1. Next, for example, a silicon oxide film having a film thickness of about 5 nm to 100 nm and a silicon nitride film having a film thickness of about 30 nm to 100 nm are deposited on an entire surface of the semiconductor substrate 1 by CVD, and thereafter, the deposited silicon oxide film and silicon nitride film are etched back, so that a side-wall insulating film 21 is formed on both side surfaces of the gate electrode 10 in the logic circuit portion L, and a buried insulating film 11 is formed between adjacent word lines 10 in the memory element portion M.

Next, a resist film (not shown) is formed, covering the memory element portion M. Using the formed resist film, and the gate electrode 10 and the side-wall insulating film 21 in the logic circuit portion L as a mask, an n-type impurity ion is selectively implanted into the semiconductor substrate 1 so that a high-concentration impurity diffusion layer 22 that will become a drain region or a source region is formed. In this case, an n-type impurity ion is selectively implanted into bit line contact portions (not shown) of the source/drain regions 5 in the memory element portion M so that a high-concentration impurity diffusion layer is formed. Here, an order in which the high-concentration impurity diffusion layer (not shown) included in the bit line contact portion of the source/drain region 5 in the memory element portion M and the high-concentration impurity diffusion layer 22 in the logic circuit portion L are formed is not particularly limited.

Next, as shown in FIG. 43C, a metal film of cobalt, nickel or the like is deposited on an entire surface of the semiconductor substrate 1 by, for example, vacuum vapor deposition or the like. Next, a heat treatment is performed with respect to the deposited metal film so that a metal silicide layer 23 is formed in upper portions of the word line 10 and the bit line contact portion in the memory element portion M, and the metal silicide layer 23 is also formed in upper portions of the gate electrode 10 and the high-concentration impurity diffusion layer 22 in the logic circuit portion L.

Subsequently, though not shown, as described in the first embodiment, an interlayer insulating film made of silicon oxide is deposited on an entire surface of the semiconductor substrate 1 by, for example, CVD. Thereafter, a plurality of connection holes for exposing the metal silicide layer on each bit line contact portion are selectively formed in the interlayer insulating film by lithography or etching. Next, a conductive film including a metal monolayer film or a metal multilayer film made of tungsten, a tungsten compound, titanium, a titanium compound (titanium nitride, etc.) or the like is deposited on an entire surface of the interlayer insulating film, burying each connection hole. Next, the deposited conductive film is subjected to patterning so that the source/drain regions 5 are connected to the deposited conductive film. Bit interconnects are thus formed from the conductive film.

Thereby, the semiconductor memory device including the logic circuit portion L in addition to the memory element portion M having a structure similar to that of the first embodiment can be obtained.

Thus, according to the fourth embodiment, an effect similar to that of the semiconductor memory device of the first embodiment can be obtained in the memory element portion M. In addition, the word line (gate electrode) 10 included in the memory element portion M and the word line (gate electrode) 10 of the transistor included in the logic circuit portion L can be formed in the same step, thereby making it possible to reduce the number of steps.

Note that, also in the fourth embodiment, the constituent materials and their film thicknesses can be changed and modified as in the first embodiment.

### Fifth Embodiment

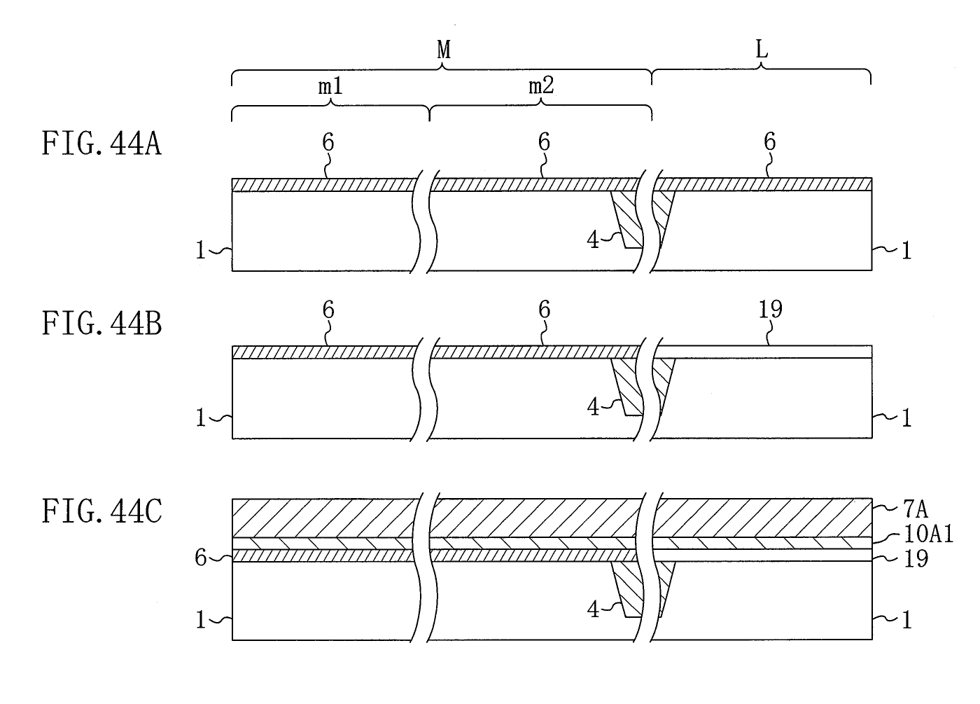

Hereinafter, a semiconductor memory device according to a fifth embodiment of the present invention and its manufacturing method will be described with reference to FIGS. 44A to 47C.

The semiconductor memory device of the fifth embodiment includes a memory element portion having a memory cell according to the second embodiment, and a logic circuit portion including a peripheral circuit or the like. Here, a method for manufacturing the semiconductor memory device of this embodiment will be described. Therefore, the memory element portion of the fifth embodiment can be manufactured by a method similar to that of the second embodiment.

Initially, as shown in FIG. 44A, a main surface of a semiconductor substrate 1 made of silicon is divided into a memory element portion M and a logic circuit portion L by an isolation region 4 (e.g., STI, etc.). Note that the memory element portion M includes a region m1 corresponding to a cross-section taken along line XVI-XVI of FIG. 15 and a region m2 corresponding to a cross-section taken along line m2-m2 of FIG. 15. The logic circuit portion L typically includes an n-channel transistor and a p-channel transistor. Since both transistors are different only in that they include impurity ions of different conductive types. Therefore, as an example, only the n-channel transistor is here shown.

Next, a trap film 6 that is an ONO film having a film thickness of 20 nm is deposited on an entire surface of the main surface of the semiconductor substrate 1 including the isolation region 4. In this case, the trap film 6 may be formed thinner by a film thickness of a gate insulating film that will be formed in the logic circuit portion L in a subsequent step.

Next, as shown in FIG. 44B, a portion of the trap film 6 that is deposited in the logic circuit portion L is removed, and thereafter, a gate insulating film 19 is made of silicon oxide (e.g., a thermal oxide film) and has a film thickness of 3 nm is selectively formed on an entire surface of the logic circuit portion L of the main surface of the semiconductor substrate 1.

Next, as shown in FIG. 44C, a first polysilicon film 10A1 having a film thickness of about 20 nm to 80 nm and a thin silicon oxide film (not shown) having a film thickness of about 10 nm are deposited on the trap film 6 and the gate insulating film 19. Next, a second mask formation film 7A made of silicon nitride having a film thickness of about 50 nm to 200 nm is formed.

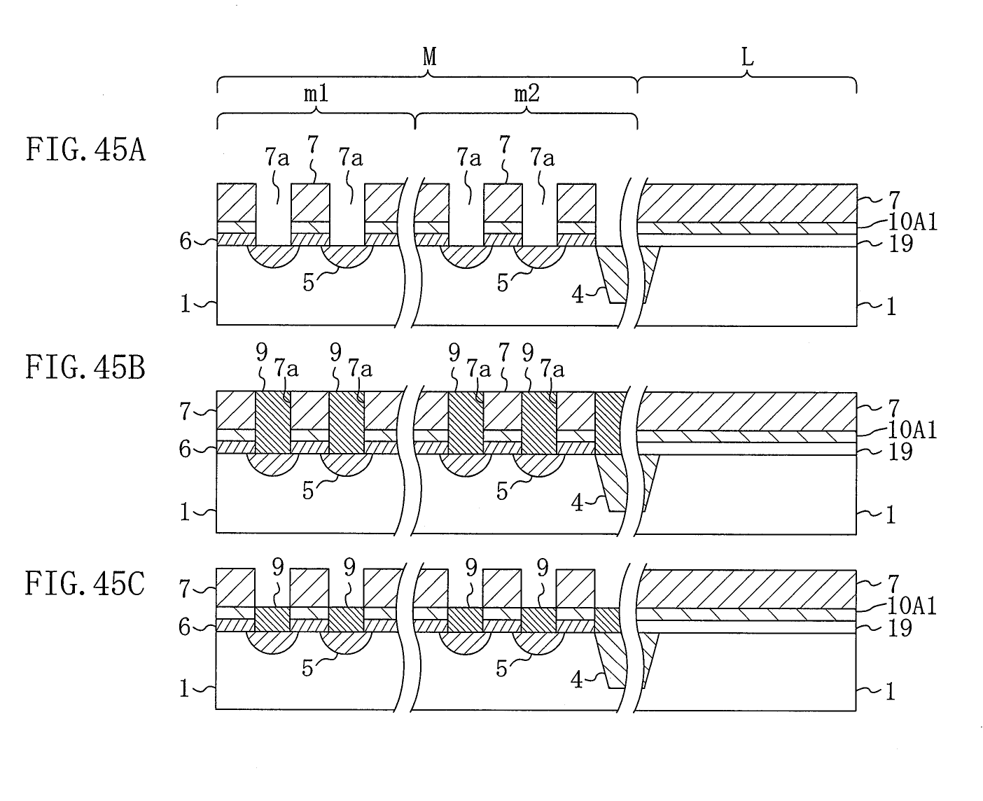

Next, as shown in FIG. 45A, stripe-shaped opening portions 7a having openings for source/drain formation regions of the memory element portion M are formed in the second mask formation film 7A by lithography and dry etching, and a second mask film 7 is obtained from the second mask formation film 7A. Further, the silicon oxide film (not shown), the first polysilicon film 10A1 and the trap film 6 that are exposed from each opening portion 7a of the second mask film 7 are successively removed by etching. Here, the opening portion 7a of the second mask film 7 has an opening width of 100 nm, which is a width of the source/drain region. On the other hand, each line width of the second mask film 7 is 150 nm, which is a channel width of a memory cell transistor. Note that, as described in the second embodiment, the trap film 6 that is exposed from each opening portion 7a of the second mask film 7 may not be necessarily removed. Next, ion implantation is performed with respect to the memory element portion M of the semiconductor substrate 1 once or twice or more using the second mask film 7 under conditions such that, for example, arsenic, which is an n-type impurity, is used, the acceleration energy is 5 keV to 200 keV, and the dose is 1×10¹⁴ cm⁻² to 1×10¹⁷ cm⁻², so that source/drain regions 5 each made of an n-type impurity diffusion layer are formed.

Next, as shown in FIG. 45B, a bit line buried oxide film 9 made of silicon oxide is deposited, burying each opening portion 7a of the second mask film 7, and thereafter, an upper surface of the bit line buried oxide film 9 is planarized.

Next, as shown in FIG. 45C, a height of the bit line buried oxide film 9 is adjusted to substantially the same height as that of the first polycrystal silicon film 10A1 by wet etching or dry etch back.

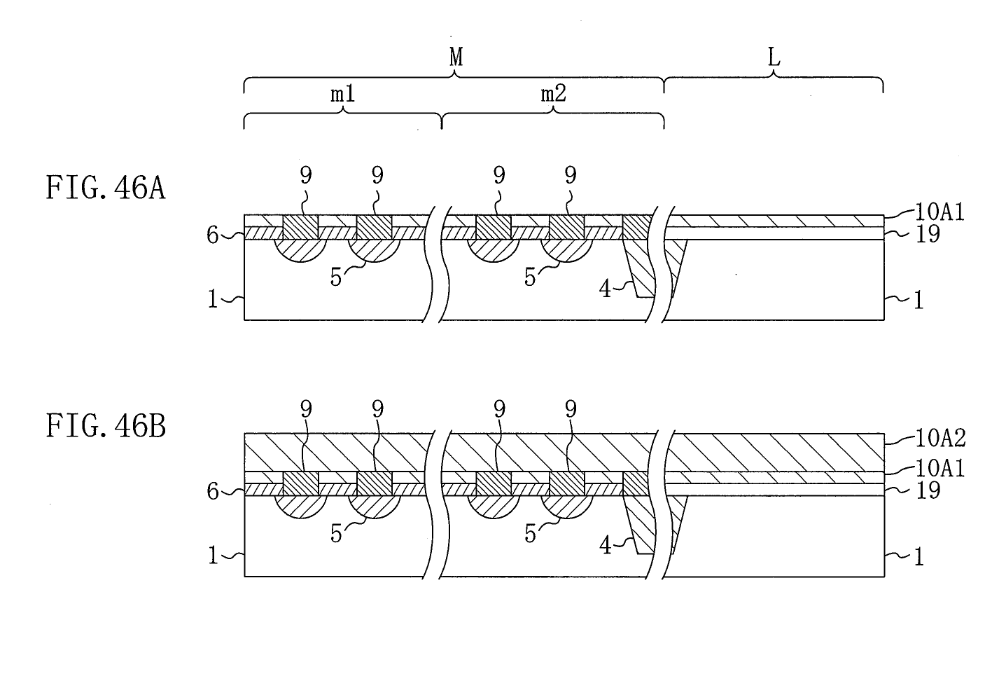

Next, as shown in FIG. 46A, only the second mask film 7 is selectively removed by wet etching or etch back, and further, the silicon oxide film (not shown) on the first polycrystal silicon film 10A1 is removed to form a bit line buried oxide film 9. Thereby, a height of the bit line buried oxide film 9 is adjusted to substantially the same height as that of the first polycrystal silicon film 10A1. This height adjusting step is performed before the removal of the second mask film 7. In order to achieve the same height more precisely, the height adjusting step is preferably performed both before and after the removal of the second mask film 7.

Next, as shown in FIG. 46B, a second polycrystal silicon film 10A2 that is doped with phosphorus, which is an n-type impurity, to about 1×10¹⁸ cm⁻³ to 1×10²² cm⁻³, is deposited on the bit line buried oxide film 9 and the first polycrystal silicon film 10A1. In this case, a very thin native oxide film having a film thickness of about 1 nm may be formed at an interface between the first polycrystal silicon film 10A1 and the second polycrystal silicon film 10A2. However, since the first polycrystal silicon film 10A1 and the second polycrystal silicon film 10A2 are electrically connected, such a native oxide film does not cause a problem when they are used as the gate electrode.

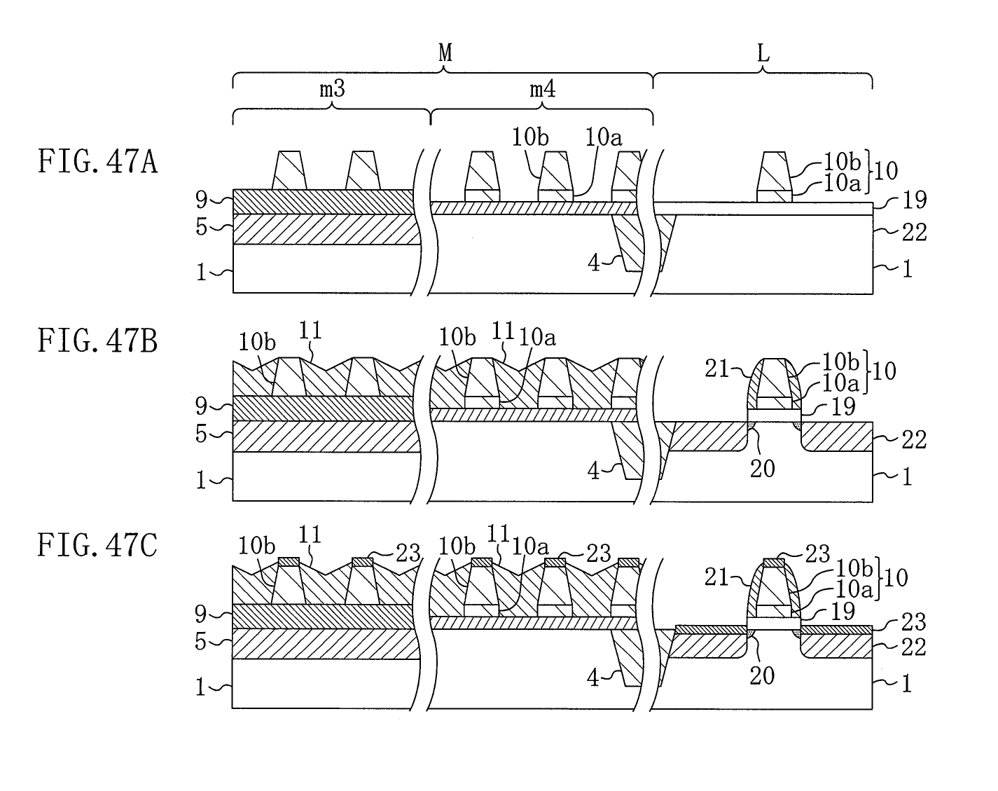

Next, as shown in FIG. 47A, the following three-step dry etching is selectively performed with respect to the deposited second polycrystal silicon film 10A2 and first polycrystal silicon film 10A1. Thereby, in the memory element portion M, word lines 10 that include the lower word lines 10a and the upper word lines 10b and intersect the source/drain regions 5 are formed from the first polycrystal silicon film 10A1 and the second polycrystal silicon film 10A2. Also, in the logic circuit portion L, a word line (gate electrode) 10 that includes the lower word line 10a and the upper word line 10b is formed from the first polycrystal silicon film 10A1 and the second polycrystal silicon film 10A2. Here, the region m3 corresponds to a cross-section taken along line XVIII-XVIII of FIG. 15, and the region m4 corresponds to a cross-section taken along line XVII-XVII of FIG. 15.

Specifically, etching is performed with respect to the second polycrystal silicon film 10A2 so that a width of both side surfaces in a direction parallel to an extending direction of the word line 10 becomes narrower toward the top (forward taper shape) (first step). Next, when a height of a lower end portion of etching becomes substantially equal to a height of the bit line buried oxide film 9, an interface oxide film (not shown) between the first polysilicon film 10A1 and the second polysilicon film 10A2 is removed (second step). Next, etching is performed with respect to the first polysilicon film 10A1 so as to obtain a side surface that is substantially perpendicular to the main surface of the semiconductor substrate 1. As an example, the side surface of the upper word line 10b is caused to have an angle of about 84°±4° in the first step. Also, the side surface of the lower word line 10a is caused to have an angle of about 90°±1° in the third step. Thereby, the trap film 6 is exposed between each word line 10 in the region m4 of the memory element portion M, and the gate insulating film 19 is exposed in the logic circuit portion L. Note that specific process conditions under which both side surfaces of the upper word line 10b is caused to have a forward taper shape and a method for switching etching steps while monitoring a film thickness during etching have been described above.

Next, as shown in FIG. 47B, an n-type impurity ion is implanted into the logic circuit portion L of the semiconductor substrate 1 using the word line (gate electrode) 10 as a mask, thereby forming a low-concentration impurity diffusion layer 20 in regions on both sides of the gate electrode 10 of the semiconductor substrate 1. Next, for example, a silicon oxide film having a film thickness of about 5 nm to 100 nm and a silicon nitride film having a film thickness of about 30 nm to 100 nm are deposited on an entire surface of the semiconductor substrate 1 by CVD, and thereafter, the deposited silicon oxide film and silicon nitride film are etched back, so that a side-wall insulating film 21 is formed on both side surfaces of the gate electrode 10 in the logic circuit portion L, and a buried insulating film 11 is formed between adjacent word lines 10 in the memory element portion M.

Next, a resist film (not shown) is formed, covering the memory element portion M. Using the formed resist film, and the gate electrode 10 and the side-wall insulating film 21 in the logic circuit portion L as a mask, an n-type impurity ion is selectively implanted into the semiconductor substrate 1 so that a high-concentration impurity diffusion layer 22 that will become a drain region or a source region is formed. In this case, an n-type impurity ion is selectively implanted into bit line contact portions (not shown) of the source/drain regions 5 in the memory element portion M so that a high-concentration impurity diffusion layer is formed. Here, an order in which the high-concentration impurity diffusion layer (not shown) included in the bit line contact portion of the source/drain region 5 in the memory element portion M and the high-concentration impurity diffusion layer 22 in the logic circuit portion L are formed is not particularly limited.

Next, as shown in FIG. 47C, a metal film of cobalt, nickel or the like is deposited on an entire surface of the semiconductor substrate 1 by, for example, vacuum vapor deposition or the like. Next, a heat treatment is performed with respect to the deposited metal film so that a metal silicide layer 23 is formed in upper portions of the upper word line 10b and the bit line contact portion in the memory element portion M, and the metal silicide layer 23 is also formed in upper portions of the upper word line 10b and the high-concentration impurity diffusion layer 22 in the logic circuit portion L.

Subsequently, though not shown, as described in the second embodiment, an interlayer insulating film made of silicon oxide is deposited on an entire surface of the semiconductor substrate 1 by, for example, CVD. Thereafter, a plurality of connection holes for exposing the metal silicide layer on each bit line contact portion are selectively formed in the interlayer insulating film by lithography or etching. Next, a conductive film including a metal monolayer film or a metal multilayer film made of tungsten, a tungsten compound, titanium, a titanium compound (titanium nitride, etc.) or the like is deposited on an entire surface of the interlayer insulating film, burying each connection hole. Next, the deposited conductive film is subjected to patterning so that the source/drain regions 5 are connected to the deposited conductive film. Bit interconnects are thus formed from the conductive film.

Thereby, the semiconductor memory device including the logic circuit portion L in addition to the memory element portion M having a structure similar to that of the second embodiment can be obtained.

Thus, according to the fifth embodiment, an effect similar to that of the semiconductor memory device of the second embodiment can be obtained in the memory element portion M. In addition, the word line (gate electrode) 10 included in the memory element portion M and the word line (gate electrode) 10 of the transistor included in the logic circuit portion L can be formed in the same step, thereby making it possible to reduce the number of steps.

Note that, also in the fifth embodiment, the constituent materials and their film thicknesses can be changed and modified as in the second embodiment.

### Sixth Embodiment

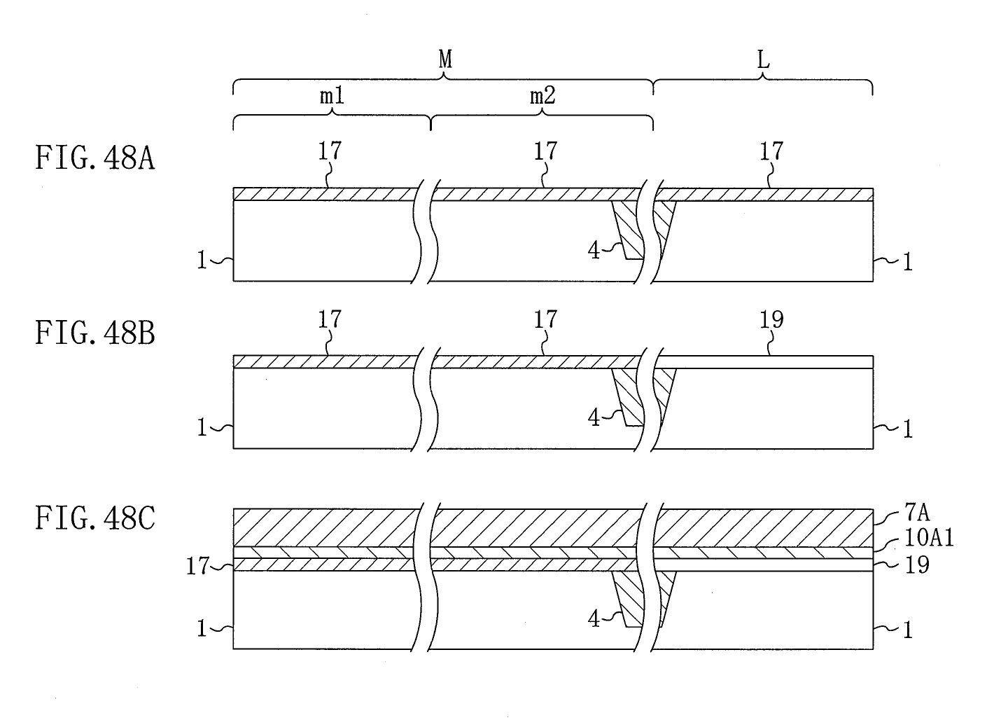

Hereinafter, a semiconductor memory device according to a sixth embodiment of the present invention and its manufacturing method will be described with reference to FIGS. 48A to 51C.

The semiconductor memory device of the sixth embodiment includes a memory element portion having a memory cell according to the third embodiment, and a logic circuit portion including a peripheral circuit or the like. Here, a method for manufacturing the semiconductor memory device of this embodiment will be described. Therefore, the memory element portion of the sixth embodiment can be manufactured by a method similar to that of the third embodiment.

Initially, as shown in FIG. 48A, a main surface of a semiconductor substrate 1 made of silicon is divided into a memory element portion M and a logic circuit portion L by an isolation region 4 (e.g., STI, etc.). Note that the memory element portion M includes a region nil corresponding to a cross-section taken along line XXVIII-XXVIII of FIG. 27 and a region m2 corresponding to a cross-section taken along line XXIX-XXIX of FIG. 27. The logic circuit portion L typically includes an n-channel transistor and a p-channel transistor. Since both transistors are different only in that they include impurity ions of different conductive types. Therefore, as an example, only the n-channel transistor is here shown.

Next, a tunnel film 17 that is made of silicon oxide and has a film thickness of 10 nm is deposited on an entire surface of the main surface of the semiconductor substrate 1 including the isolation region 4. In this case, the tunnel film 17 may be formed thinner by a film thickness of a gate insulating film that will be formed in the logic circuit portion L in a subsequent step.

Next, as shown in FIG. 48B, a portion of the tunnel film 17 that is deposited in the logic circuit portion L is removed, and thereafter, a gate insulating film 19 is made of silicon oxide (e.g., a thermal oxide film) and has a film thickness of 3 nm is selectively formed on an entire surface of the logic circuit portion L of the main surface of the semiconductor substrate 1.

Next, as shown in FIG. 48C, a n-type conductivity first polysilicon film 10A1 having a film thickness of about 20 nm to 80 nm and a thin silicon oxide film (not shown) having a film thickness of about 10 nm are successively deposited on the tunnel film 17 and the gate insulating film 19. Next, a second mask formation film 7A made of silicon nitride having a film thickness of about 50 nm to 200 nm is formed.

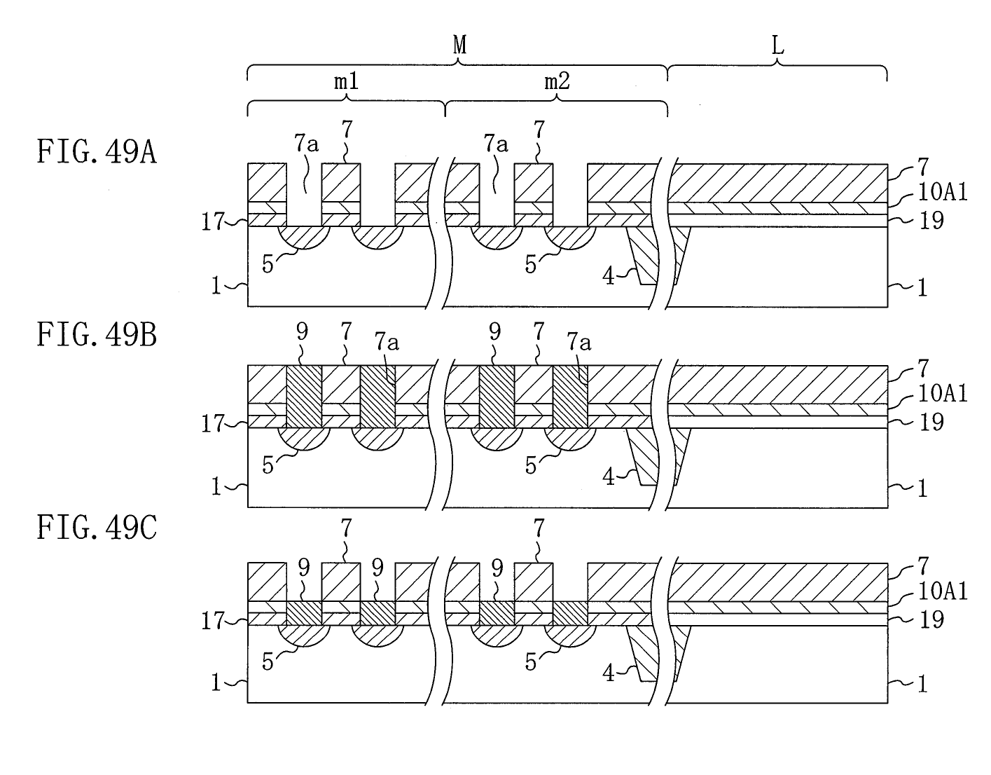

Next, as shown in FIG. 49A, stripe-shaped opening portions 7a having openings for source/drain formation regions of the memory element portion M are formed in the second mask formation film 7A by lithography and dry etching, and a second mask film 7 is obtained from the second mask formation film 7A. Further, the silicon oxide film (not shown), the first polysilicon film 10A1 and the tunnel film 17 that are exposed from each opening portion 7a of the second mask film 7 are successively removed by etching. Here, the opening portion 7a of the second mask film 7 has an opening width of 100 nm, which is a width of the source/drain region. On the other hand, each line width of the second mask film 7 is 150 nm, which is a channel width of a memory cell transistor. Note that, as described in the third embodiment, the tunnel film 17 that is exposed from each opening portion 7a of the second mask film 7 may not be necessarily removed. Next, ion implantation is performed with respect to the memory element portion M of the semiconductor substrate 1 once or twice or more using the second mask film 7 under conditions such that, for example, arsenic, which is an n-type impurity, is used, the acceleration energy is 5 keV to 200 keV, and the dose is 1×10¹⁴ cm⁻² to 1×10¹⁷ cm⁻², so that source/drain regions 5 each made of an n-type impurity diffusion layer are formed.

Next, as shown in FIG. 49B, a bit line buried oxide film 9 made of silicon oxide is deposited, burying each opening portion 7a of the second mask film 7, and thereafter, an upper surface of the bit line buried oxide film 9 is planarized.

Next, as shown in FIG. 49C, a height of the bit line buried oxide film 9 is adjusted to substantially the same height as that of the first polycrystal silicon film 10A1 by wet etching or dry etch back.

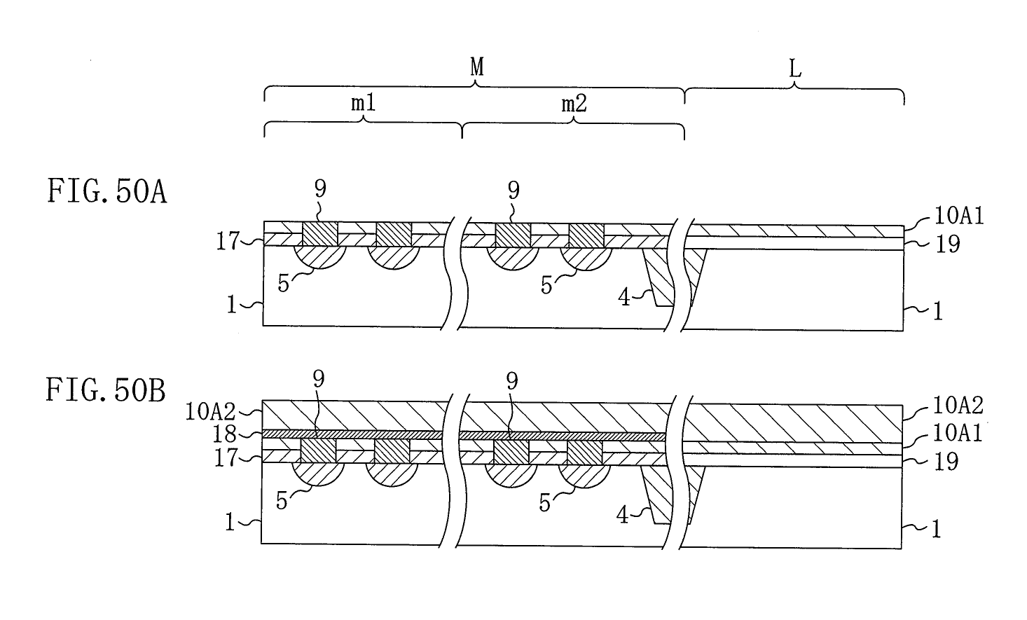

Next, as shown in FIG. 50A, only the second mask film 7 is selectively removed by wet etching or etch back, and further, the silicon oxide film (not shown) on the first polycrystal silicon film 10A1 is removed to form a bit line buried oxide film 9. Thereby, a height of the bit line buried oxide film 9 is adjusted to substantially the same height as that of the first polycrystal silicon film 10A1. This height adjusting step is performed before the removal of the second mask film 7. In order to achieve the same height more precisely, the height adjusting step is preferably performed both before and after the removal of the second mask film 7.

Next, as shown in FIG. 50B, an interelectrode insulating film 18 that is a multilayer film made of silicon oxide, silicon nitride and silicon oxide is deposited on the first polycrystal silicon film 10A1 and the bit line buried oxide film 9. Thereafter, the deposited interelectrode insulating film 18 is selectively removed from the logic circuit portion L. Next, a second polycrystal silicon film 10A2 that is doped with phosphorus, which is an n-type impurity, to about 1×10¹⁸ cm⁻³ to 1×10²² cm⁻³, is deposited on an entire surface of the memory element portion M and the logic circuit portion L of the semiconductor substrate 1.

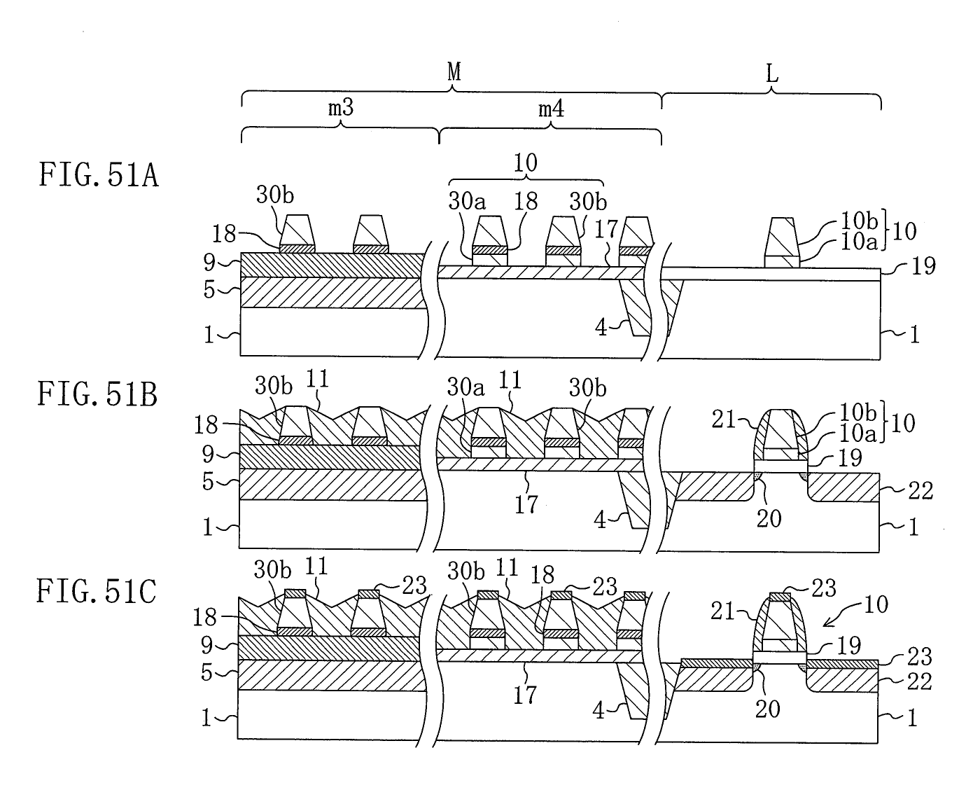

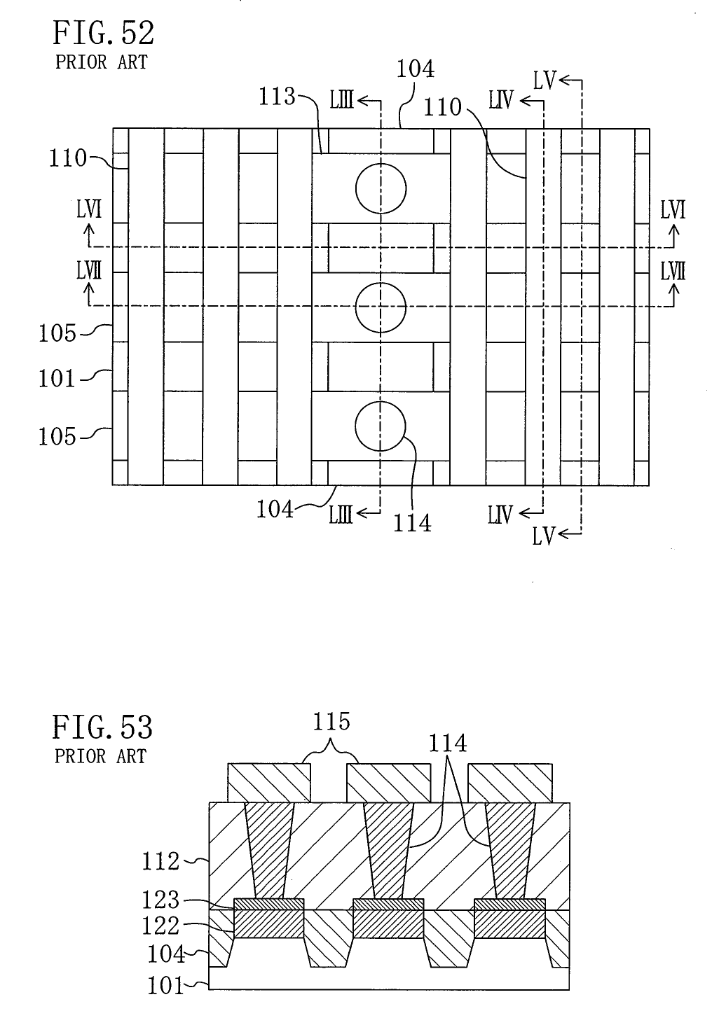

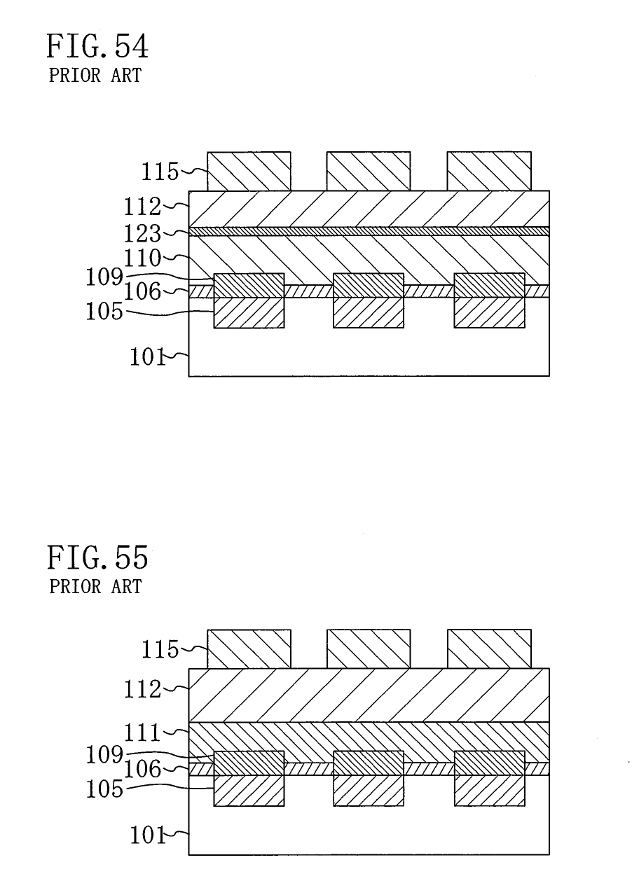

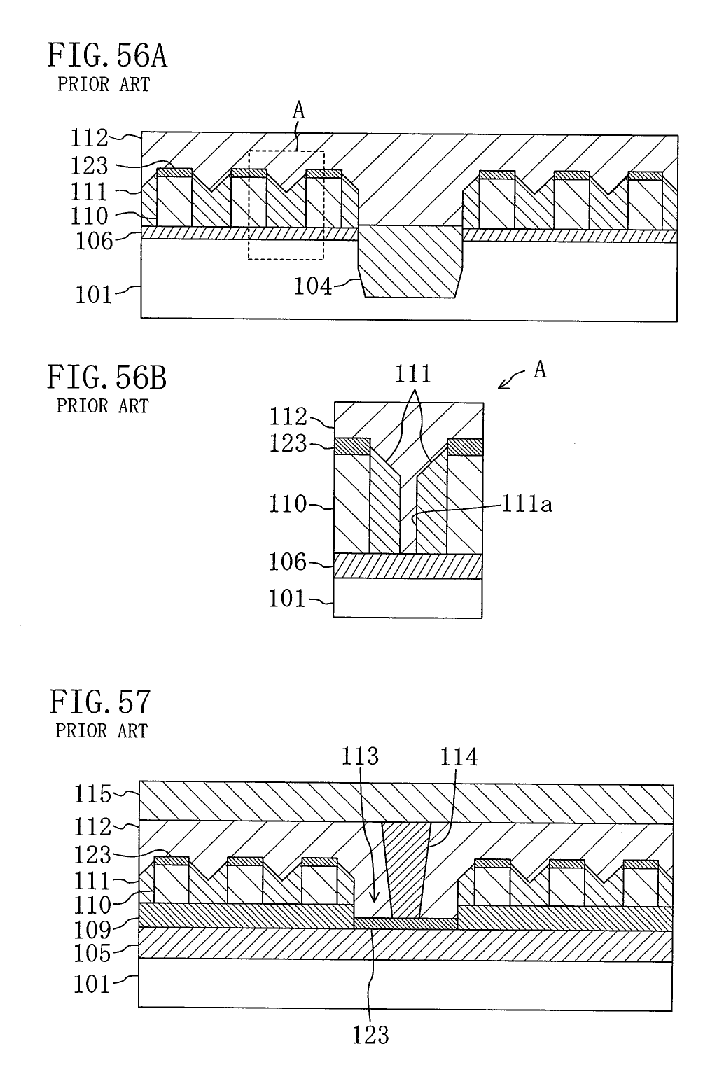

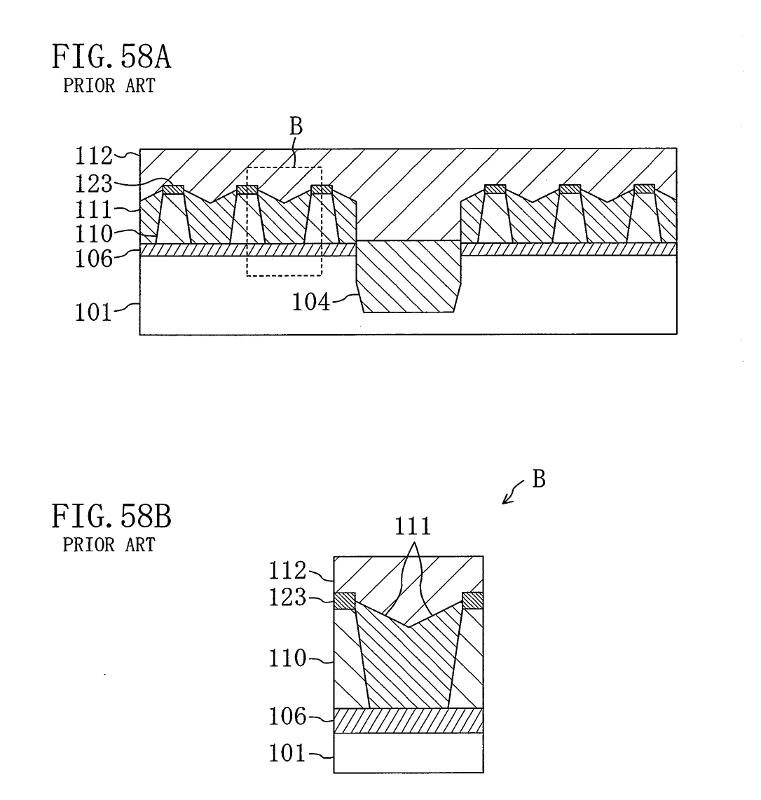

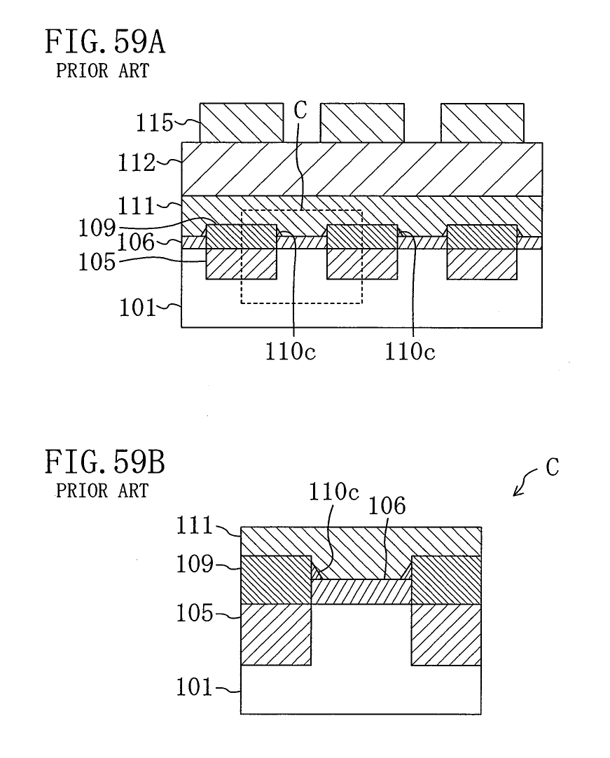

Next, as shown in FIG. 51A, the following three-step dry etching is selectively performed with respect to the deposited second polycrystal silicon film 10A2, interelectrode insulating film 18 and first polycrystal silicon film 10A1. Thereby, in the memory element portion M, word lines 10 that include a floating gate electrode 30a, the interelectrode insulating film 18 and a control gate electrode 30b and intersect the source/drain regions 5 are formed from the first polycrystal silicon film 10A1, the interelectrode insulating film 18 and the second polycrystal silicon film 10A2. Also, in the logic circuit portion L, a word line (gate electrode) 10 that includes a lower word line 10a and an upper word line 10b is formed from the first polycrystal silicon film 10A1 and the second polycrystal silicon film 10A2. Here, the region m3 corresponds to a cross-section taken along line XXXI-XXXI of FIG. 27, and the region m4 corresponds to a cross-section taken along line XXX-XXX of FIG. 27.

Specifically, etching is performed with respect to the second polycrystal silicon film 10A2 so that a width of both side surfaces in a direction parallel to an extending direction of the word line 10 becomes narrower toward the top (forward taper shape) (first step). Next, when a height of a lower end portion of etching becomes substantially equal to a height of the interelectrode insulating film 18, the interelectrode insulating film 18 is removed (second step). Next, etching is performed with respect to the first polysilicon film 10A1 so as to obtain a side surface that is substantially perpendicular to the main surface of the semiconductor substrate 1. As an example, the side surface of the control gate electrode 30b is caused to have an angle of about 84°±4° in the first step. Also, the side surface of the floating gate electrode 30a is caused to have an angle of about 90°±1° in the third step. Thereby, the tunnel film 17 is exposed between each word line 10 in the region m4 of the memory element portion M, and the gate insulating film 19 is exposed in the logic circuit portion L. Note that specific process conditions under which both side surfaces of the floating gate electrode 30b is caused to have a forward taper shape and a method for switching etching steps while monitoring a film thickness during etching have been described above. Specifically, the switching of etching steps may include switching etching conditions while monitoring the film thickness during etching as in the first embodiment. Alternatively, a change in intensity of plasma light emission may be detected while the interface oxide film remains interposed, as in the third embodiment.

Next, as shown in FIG. 51B, an n-type impurity ion is implanted into the logic circuit portion L of the semiconductor substrate 1 using the word line (gate electrode) 10 as a mask, thereby forming a low-concentration impurity diffusion layer 20 in regions on both sides of the gate electrode 10 of the semiconductor substrate 1. Next, for example, a silicon oxide film having a film thickness of about 5 nm to 100 nm and a silicon nitride film having a film thickness of about 30 nm to 100 nm are deposited on an entire surface of the semiconductor substrate 1 by CVD, and thereafter, the deposited silicon oxide film and silicon nitride film are etched back, so that a side-wall insulating film 21 is formed on both side surfaces of the gate electrode 10 in the logic circuit portion L, and a buried insulating film 11 is formed between adjacent word lines 10 in the memory element portion M.

Next, a resist film (not shown) is formed, covering the memory element portion M. Using the formed resist film, and the gate electrode 10 and the side-wall insulating film 21 in the logic circuit portion L as a mask, an n-type impurity ion is selectively implanted into the semiconductor substrate 1 so that a high-concentration impurity diffusion layer 22 that will become a drain region or a source region is formed. In this case, an n-type impurity ion is selectively implanted into bit line contact portions (not shown) of the source/drain regions 5 in the memory element portion M so that a high-concentration impurity diffusion layer is formed. Here, an order in which the high-concentration impurity diffusion layer (not shown) included in the bit line contact portion of the source/drain region 5 in the memory element portion M and the high-concentration impurity diffusion layer 22 in the logic circuit portion L are formed is not particularly limited.

Next, as shown in FIG. 51C, a metal film of cobalt, nickel or the like is deposited on an entire surface of the semiconductor substrate 1 by, for example, vacuum vapor deposition or the like. Next, a heat treatment is performed with respect to the deposited metal film so that a metal silicide layer 23 is formed in upper portions of the control gate electrode 30b and the bit line contact portion in the memory element portion M, and the metal silicide layer 23 is also formed in upper portions of the upper word line 10b and the high-concentration impurity diffusion layer 22 in the logic circuit portion L.

Subsequently, though not shown, as described in the third embodiment, an interlayer insulating film made of silicon oxide is deposited on an entire surface of the semiconductor substrate 1 by, for example, CVD. Thereafter, a plurality of connection holes for exposing the metal silicide layer on each bit line contact portion are selectively formed in the interlayer insulating film by lithography or etching. Next, a conductive film including a metal monolayer film or a metal multilayer film made of tungsten, a tungsten compound, titanium, a titanium compound (titanium nitride, etc.) or the like is deposited on an entire surface of the interlayer insulating film, burying each connection hole. Next, the deposited conductive film is subjected to patterning so that the source/drain regions 5 are connected to the deposited conductive film. Bit interconnects are thus formed from the conductive film.

Thereby, the semiconductor memory device including the logic circuit portion L in addition to the memory element portion M having a structure similar to that of the third embodiment can be obtained.

Thus, according to the sixth embodiment, an effect similar to that of the semiconductor memory device of the third embodiment can be obtained in the memory element portion M. In addition, the word line (gate electrode) 10 that includes the floating gate electrode 30a, the interelectrode insulating film 18 and the control gate electrode 30b and is included in the memory element portion M, and the word line (gate electrode) 10 of the transistor included in the logic circuit portion L can be formed in the same step, thereby making it possible to reduce the number of steps.

Note that, also in the sixth embodiment, the constituent materials and their film thicknesses can be changed and modified as in the third embodiment.

Each of the above-described first to sixth embodiments is not limited to a non-volatile semiconductor memory device called a flash memory device, and is applicable to a semiconductor memory device in which bit lines and word line intersecting each other are integrated in a high packing density, as in the non-volatile semiconductor memory device. As an example, the present invention is also applicable to a non-volatile semiconductor memory device, such as a dynamic random access memory (DRAM) or the like, a magnetic random access memory (MRAM), a resistive random access memory (RRAM), a ferroelectric random access memory (FRAM), or the like.

As described above, the semiconductor memory device of the present invention and its manufacturing method provides a semiconductor memory device that has bit lines made of a diffusion layer formed in a semiconductor region, the bit lines being spaced from each other, and word lines intersecting the bit lines, the word lines being spaced from each other, and in which a void is suppressed from occurring in an insulating film between each word line, and a etching residue caused by patterning of the word lines is also suppressed, and are particularly useful as a non-volatile semiconductor memory device and its manufacturing method, or the like.

1. A semiconductor memory device comprising:
a plurality of word line provided on a semiconductor region, extending in a row direction;
a plurality of bit lines provided in the semiconductor region, extending in a column direction,
a plurality of memory elements provided at intersections between the plurality of word lines and the plurality of bit lines; and
a plurality of bit line buried insulating films covering upper portions of the plurality of bit lines,
wherein each of the plurality of word lines provides a first electrically single gate electrode with an equipotential structure in the corresponding one of the plurality of memory elements,
a lower portion of a side surface of each of the plurality of word lines in a direction parallel to an extending direction of the word line is perpendicular to a main surface of the semiconductor region, and an upper portion of the side surface is inclined so that a width thereof becomes smaller toward a top thereof, and
a height of the bit line buried insulating films is substantially the same as a height of the lower portion of the side surface of each of the plurality of word lines.

2. The semiconductor memory device of claim 1, wherein
each of the plurality of word lines includes a multilayer film including a lower-layer film and an upper-layer film provided on the lower-layer film,
a side surface of the lower-layer film in the direction parallel to the extending direction of the word line is perpendicular to the main surface of the semiconductor region, and
a side surface of the upper-layer film in the direction parallel to the extending direction of the word line is inclined so that a width of a cross-section thereof becomes smaller toward a top thereof.

3. The semiconductor memory device of claim 1, wherein
each of the plurality of memory elements has a trap film for accumulating electric charges, wherein the trap film serves as a gate insulating film.

4. The semiconductor memory device of claim 3, wherein
the gate insulating film is a multilayer film that is a stack of a lower-layer silicon oxide film, a charge-accumulating silicon nitride film and an upper-layer silicon oxide film that are successively formed, the lower-layer silicon oxide film being closest to the semiconductor region.

5. (canceled)

6. The semiconductor memory device of claim 1, wherein
each of the plurality of bit lines includes an impurity diffusion layer that is selectively provided in an upper portion of the semiconductor region.

7. The semiconductor memory device of claim 6, wherein
the impurity diffusion layer includes a first impurity diffusion layer, and a second impurity diffusion layer provided around the first impurity diffusion layer.

8. The semiconductor memory device of claim 7, wherein
an impurity concentration of the first impurity diffusion layer is higher than an impurity concentration of the second impurity diffusion layer.

9. The semiconductor memory device of claim 1, further comprising:
a plurality of bit line buried insulating films covering upper portions of the plurality of bit lines,
wherein a height of the bit line buried insulating film is substantially the same as a height of the lower portion of the side surface of the word line.

10. The semiconductor memory device of claim 2, wherein
the lower-layer film and the upper-layer film are made of polycrystal silicon or amorphous silicon.

11. The semiconductor memory device of claim 10, wherein
a metal silicide layer is provided in an upper portion of the upper-layer film.

12. The semiconductor memory device of claim 2, wherein
at least the upper-layer film of the word line is a metal film.

13. The semiconductor memory device of claim 6, further comprising:
a plurality of bit interconnects provided above the semiconductor region, each of the plurality of bit interconnects being electrically connected to the corresponding one of the bit lines via a corresponding contact,
wherein a metal silicide layer is provided in a region where the bit line is connected to the contact.

14. The semiconductor memory device of claim 2, further comprising:
a logic circuit portion provided in a region excluding the plurality of memory elements of the semiconductor region, the logic circuit portion including a transistor having a second gate electrode,
wherein the second gate electrode includes a multilayer film having the same configuration as that of the word line including the lower-layer film and the upper-layer film.

15-32. (canceled)
